(19) United States
(12) Patent Application Publication
(10) Pub. No.: US 2010/0188148 A1
(43) Pub. Date: Jul. 29, 2010

(54) PREDISTORTION MECHANISM FOR COMPENSATION OF TRANSISTOR SIZE MISMATCH IN A DIGITAL POWER AMPLIFIER

(75) Inventors: Jaimin A. Mehta, Plano, TX (US); Sameh S. Rezeq, Dallas, TX (US); Manouchehr Entezari, Highland Village, TX (US); Robert B. Staszewski, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 12/359,613

(22) Filed: Jan. 26, 2009

(51) Int. Cl. H03F 1/26

(52) U.S. Cl. 330/149

(57) ABSTRACT

A novel and useful apparatus for and method of predistortion compensation of device (e.g., transistor) mismatch in a digital power amplifier (DPA). The device mismatch predistortion mechanism of the present invention addresses the problem of matching between two types of binary weighted transistors, whereby mismatched transistors cause degradation in wideband noise. The invention provides a digital predistortion mechanism which functions to pre-distort the mismatch ratio based on a data table calculated a priori enabling a polar transmitter to meet output spectrum and error vector magnitude (EVM) requirements of the particular modern wideband wireless standard, such as GSM, 3G WCDMA, etc.

### FIELD OF THE INVENTION

The present invention relates to the field of data communications and more particularly relates to an apparatus for and method of predistortion compensation of transistor size mismatch in a digital power amplifier.

### BACKGROUND OF THE INVENTION

With the explosive growth of the cellular phone industry, the need has arisen to reduce the cost and power consumption of mobile handsets. In addition, the recent market demand for ultra-low-cost cell phones by billions of first time users in the developing countries has spurred development of single-chip radios that integrate an RF transceiver with a digital baseband (DBB) processor in scaled CMOS. To reduce costs, the entire radio, including memory, application processor, digital baseband processor, analog baseband and RF circuits, would ideally be all integrated onto a single silicon die with a minimal count of external components.

The goal of a complete phone-on-a-chip has not yet been realized due to various integration issues of low-voltage CMOS with 2-watt RF power amplifiers, 20-V battery chargers and receiver band-pass RF SAW filters. Thus, the integration at the RF and DBB level still provides the lowest cost solution, even though it has repeatedly proven to be a complex technological challenge.

To further drive cost down, transition to a nanoscale digital CMOS technology (feature size ≦100 nm) with no mask adders is necessary. RF and analog coexistence with larger scale digital circuitry in nanoscale digital CMOS, however, presents numerous issues. Many of these problems are mitigated by transforming the RF functionality into an all digital architecture of a frequency synthesizer and transmitter or a digitally intensive discrete-time architecture of a receiver.

Despite these recent architectural advances, the core RF circuits still experience some of the conventional RF system issues, such as device parameter spread and mismatch, performance variability due to environmental conditions and parasitic coupling. Integration of analog/RF circuits with digital processors brings tremendous benefits of using freely available but powerful digital logic and memory to assist in calibration, compensation, linearization, predistortion, built-in self-test (BIST), etc.

Digital RF processing techniques are focused on using digitally-intensive signal processing methods in RF to deliver the ever-increasing levels of wireless terminal functionality in a shrinking form factor. Prior art techniques include, for example, the Digital RF Processor (DRP) platform which transforms the RF functionality into a digital or digitally intensive implementation such that it reaps all the well-known benefits of digital design and automation flow.

At the core of the DRP architecture is an all-digital PLL (ADPLL) which functions to generate the local oscillator (LO) signal and almost all other clocks. An ADPLL-based transmitter employs polar architecture with all-digital phase/frequency and amplitude modulation paths.

The all-digital RF polar transmitter architecture is amenable for nanometer-scale CMOS integration. The use of low-voltage deep submicron CMOS processes allows for an unprecedented degree of scaling and integration in digital circuitry, but complicates implementation of traditional RF circuits. Furthermore, any mask adders for RF/analog circuits are not acceptable from a fabrication cost standpoint.

Consequently, a strong incentive has arisen to find digital architectural solutions to the RF functions. Areas currently in focus are phase/frequency and amplitude modulations of an RF carrier realized using a digitally-controlled oscillator (DCO) and a digitally-controlled power amplifier (DPA) circuits, respectively. They are digitally-intensive equivalents of the conventional voltage-controlled oscillator (VCO) and power amplifier (PA) driver circuits. Due to the fine feature size and high switching speed of the modern CMOS technology, the respective digital-to-frequency conversion (DFC) and digital-to-RF-amplitude conversion (DRAC) transfer functions could be made very linear and of high dynamic range.

A block diagram illustrating an example prior art polar transmitter is shown in FIG. 1. The architecture avoids the typical obstacles to RF integration which include: (1) biasing currents that are commonly used in analog designs; (2) reliance on voltage resolution with ever decreasing supply voltages and increasing noise and interferer levels; and (3) use of nonstandard devices that are not needed for memory and digital circuits, which constitute the majority of the silicon die area of a System on Chip (SoC).

The polar transmitter, generally referenced 10, comprises CORDIC and polar signal processing block 12, digital to frequency conversion block (DFC) 24 and Digital to RF amplitude conversion block (DRAC) 18. The DFC 24 comprises a modulator 26 and digitally controlled oscillator (DCO) 28. The DRAC 18 comprises a modulator 20 and digital power amplifier (DPA) 22.

Polar modulation relies on splitting the digital IQ baseband signal into a phase (i.e. frequency) data sample stream, i.e. Frequency Control Word (FCW) 16, and amplitude data sample stream, i.e. Amplitude Control Word (ACW) 14. The phase signal θ (or differentiated phase signal (f=Δθ/Δt) ) is used to directly modulate a digitally controlled oscillator (DCO), the output of which is then combined with the amplitude signal ρ in a Digital Power Amplifier (DPA).

The digital back-end of the transmitter 10 comprises dense and fast logic to perform sophisticated digital signal processing. Low-cost logic and memory is also used to fix any imperfections of analog devices. The tiny and well-matched devices allow for precise and high resolution conversions from digital to two analog domains, namely (1) RF frequency/phase and (2) RF amplitude.

The I and Q samples of the Cartesian coordinate system generated in a digital baseband (DBB) are converted through CORDIC algorithm 12 into amplitude and phase samples of the polar coordinate system. The phase is then differentiated to obtain frequency deviation. The polar signals are then conditioned through signal processing to sufficiently increase the sampling rate in order to reduce the quantization noise density and lessen the effects of the modulating spectrum replicas. The frequency deviation output signal is fed into the DCO based DFC 14, which produces a phase modulated (PM) digital carrier

y_{PM}(t)=sgn(cos(ω₀t+θ[k])) (1)

where

sgn(x)=1 for x≧0;

sgn(x)=−1 for x<0;

ω₀=2πf₀ is the angular RF carrier frequency;

θ[k] is the modulating baseband phase of the k^{th} sample.

The phase θ(t)=∫_{-∞}^{t}f(t)dt is an integral of frequency deviation, where t=k·T₀ with T₀ being the sampling period.

The amplitude modulation (AM) signal controls the envelope of the phase-modulated carrier by means of the DPA based DRAC 18. Higher-order harmonics of the digital carrier are filtered out by a matching network so that the sgn( ) operator is dropped. The composite DPA output comprises the desired RF output spectrum.

y_{RF}(t)=a[k]·cos(ω₀t+θ[k]) (2)

where, a[k] is the modulating baseband amplitude of the k^{th} sample.

While digital polar modulated transmitters have been demonstrated for GSM, GPRS, EDGE (GGE), their usage for 3G (WCDMA) and other wideband wireless standards remains a daunting task. Polar modulation relies on splitting the digital IQ baseband signal into a phase (i.e. frequency) and amplitude bit stream. The phase signal θ (or differentiated phase signal (f=Δθ/Δt)) is used to directly modulate a digitally controlled oscillator (DCO), the output of which is then combined with the amplitude signal ρ in a Digital Power Amplifier (DPA). The θ (or f=Δθ/Δt) component generated when passing the WCDMA IQ signal through a CORDIC spreads significantly due to the nonlinear (i.e. arctan) operation. The resulting signal is no longer band limited and thus theoretically infinite modulation of the oscillator is needed to represent this phase signal.

A block diagram illustrating a generic prior art modulator having a uniform array of conversion devices is shown in FIG. 2. The circuit, generally referenced 170, comprises a unit weighted encoder 172 for generating an integer stream, sigma-delta modulator 174 for generating a high speed dither stream and conversion cell block 176 including conversion cells 177 and 178 which generate the “analog” output signal.

Realization of the two “DAC” converters, where “A” stands for frequency/phase or RF amplitude analog domain, are best realized using a topology such as shown in FIG. 2. The conversion cell elements 177, 178 are unit-weighted. Further resolution improvement is achieved through high-speed ΣΔ dithering. Consequently, the integer part of the modulator is realized as a binary-to-unit-weighted encoder and the fractional part as a ΣΔ modulator.

A practical realization of the converter circuit of FIG. 2 would result in no more than 8-bits of integer resolution. To break that limitation, a modulator structure with segmented arrays of conversion devices in which the ratio of the larger to smaller device weighting is typically a power of two is shown in FIG. 3 which illustrates a generic prior art modulator having a segmented array of conversion devices. Thus, an extra few bits of resolution can be achieved.

The circuit of FIG. 3, generally referenced 180, comprises a unit weighted encoder 182 for generating an integer stream, sigma-delta modulator 184 for generating a high speed dither stream and conversion cell block 186 including conversion cells 187, 188 and 189 which generate the “analog” output signal.

The binary-to-unit-weighted encoding redundancy in FIGS. 2 and 3 (e.g., code 3 could activate any three devices, which are not necessarily adjacent) could be further exploited to improve the linearity of conversion. Dynamic element matching (DEM), an example of a technique borrowed from the analog data converter field, is used to perform rotation of active elements every cycle of the data clock. This way, any device mismatch will be averaged out over the number of participating devices.

A schematic diagram illustrating a prior art digital to RF amplitude converter (DRAC) is shown in FIG. 4. The DRAC, generally referenced 190, comprises a controllable switch array 191 coupled to the DCO 192 output and matching network 201 coupled to antenna 208. The controllable switch array comprises gates 194 and transistors 196. The matching network comprises capacitors 198, 204 and inductors 200, 202, 206.

The direct digital-to-RF-amplitude converter (DRAC), efficiently combines the traditional transmit chain functions of D/A conversion, filtering, buffering and mixing or RF output amplitude control into one single circuit. The DPA operates as a pseudo-class-E RF power amplifier and is driven by a square wave, which is the phase modulated signal from the all-digital PLL (ADPLL). The array of NMOS transistors 196 is used as on/off switches with a certain resistance. The matching network components are chosen to provide a bidirectional current source, second harmonic rejection, switching noise filtering and critically dampening the switch output. The control logic for each switch comprises an RF digital AND gate 194 whose inputs are the phase-modulated output of the ADPLL and part of the amplitude control word from a digital control block.

In order to achieve the tight quantization phase noise floor necessitated by cellular modulation schemes, the DPA typically needs to have better than 10 bits of integer resolution. Fractional resolution is achieved by ΣΔ dithering of the LSB transistors. To achieve such requirements while ensuring monotonic amplitude transfer function characteristics in the presence of device variability necessitates the use of a segmented structure (as shown in FIG. 3), i.e. DPA transistors are implemented as 1× and N× devices, where N is chosen to be 4, 8 or 16, etc. The 1× devices are referred to as LSB transistors and the 4, 8, 16, etc. devices as MSB transistors.

A problem, however, is that the performance of such a DPA structure is susceptible to not only the systematic and random mismatches in these LSB and MSB devices but also to the systematic sizing ratio mismatch between the MSB/LSB devices. Such a mismatch can invariably occur in spite of following the best circuit layout practices due to the fabrication lithographic process tolerances that impact the MSB and LSB devices differently.

A graph illustrating the effects of compression and device mismatch on the DPA output voltage function versus DPA input digital code in the presence of MSB/LSB device mismatch is shown in FIG. 5. A further problem is that MSB and LSB devices typically exhibit random variability of between 4% and 10% standard deviation, respectively. In addition, MSB devices that are larger than N times 1× devices, generate slightly higher output power than in the absence of such a mismatch and vice versa.

Note that the straight line 217 represents the ideal input/output voltage relationship. In reality, however, AM to AM compression causes the compressed curve 219. The samples making up both curves 233, 231 include both 1× and 4× samples. The mismatch ratio at low input codes is minimal as curve 233 is almost a straight line. At higher input codes, however, the effects of device mismatch are apparent in the curve 231. The first sample in each sequence of four adjacent samples is a 4× sample. The following three samples are 1× samples. Note the large jump from the last 1× sample in a sequence to the 4× sample in the subsequent sequence.

A graph illustrating the effects of compression and device mismatch on the DPA differential step size as a function of DPA input digital code is shown in FIG. 6. The graph shows that the DPA step size is not uniform across the input digital code. In addition, the effects of compression on the differential voltage step size of the DPA are also evident. At lower codes (curve 235) the DPA step size is somewhat periodic because of the parity between LSB and MSB step sizes. At higher DPA input codes (curve 237), however, the MSB/LSB mismatch also gets compressed at higher DPA input codes. This nonlinear behavior is process, voltage and temperature dependent and can be further aggravated if, for example, the drive strengths of the MSB and LSB are not designed carefully. This level of dynamic nonlinearity (DNL) is not acceptable and severely degrades the fidelity of amplitude modulation. Such a periodic pattern emanating from MSB/LSB transistors not only degrades the close-in performance of the polar transmitter due to spectral regrowth but also has the potential to create spurious content in the complex modulated envelope output from the polar transmitter.

It is noted that the mismatch behavior can change between different power levels. The reason for this is that the drive capability of the 1× sized transistors is different from that of the 4× sized transistors. Therefore, in AM to AM compression regions, the 1× output may compress more or less than compared with that of the 4× output.

There is thus a need for a mechanism that addresses the device mismatch problem that overcomes the disadvantages of the prior art techniques. The mechanism should be able to eliminate or mitigate as much as possible the degradation caused by the mismatch between different size transistors (i.e. MSB and LSB devices) in the DRAC which would otherwise lead to degradation in wideband noise at the output of the transmitter. The mechanism should preferably be implementable as a simple, all digital implementation having relatively low area and simple production requirements and be capable of enabling a polar transmitter to be used with both narrowband and wideband modulation schemes.

### SUMMARY OF THE INVENTION

The present invention is a novel and useful apparatus for and method of predistortion compensation of device (e.g., transistor) mismatch in a digital power amplifier (DPA). The device mismatch predistortion mechanism of the present invention addresses the problem of matching between two types/sizes of unit weighted transistors, whereby mismatched transistors cause degradation in wideband noise.

The invention provides a digital predistortion mechanism which functions to pre-distort the mismatch ratio based on a lookup data table calculated a priori enabling a polar transmitter to meet output spectrum and error vector magnitude (EVM) requirements of the particular modern wideband wireless standard, such as GSM, 3G WCDMA, etc.

The device mismatch predistortion mechanism described herein is suitable for use in any application implementing an RF digital to analog converter (DAC), e.g., DPA, etc., employing polar modulation that utilizes multiple types of binary weighted devices or transistors to achieve the desired amplitude path resolution. An example application is provided of a single chip radio, e.g., WCDMA, etc., that integrates the RF circuitry with the digital base band (DBB) circuitry on the same die.

In operation, the device mismatch predistortion mechanism is operative to pre-calculate the number of 1× devices (transistors) to be used for a particular portion of amplitude modulation. This information along with previously recorded device mismatch information is used to correct the mismatch. A lookup table is provided for storing pre-calculated correction values representing the ratio between the two different sized devices for different values of the DPA digital input code. The integer MSB portion of an amplitude code word is used to address the table while the correction values output of the table are multiplied by the integer LSB portion of the amplitude code word.

Several advantages of the device mismatch predistortion mechanism of the present invention include (1) minimal area required to implement the mechanism; (2) the mechanism achieves better performance than without the use thereof; (3) the mechanism can be implemented entirely digitally (i.e. no analog constraints), and its performance is entirely predictable; (4) the mechanism is relatively simple to implement and manufacture for production; and (5) the mechanism requires negligible chip area and exhibits very low power consumption.

Note that some aspects of the invention described herein may be constructed as software objects that are executed in embedded devices as firmware, software objects that are executed as part of a software application on either an embedded or non-embedded computer system such as a digital signal processor (DSP), microcomputer, minicomputer, microprocessor, etc. running a real-time operating system such as WinCE, Symbian, OSE, Embedded LINUX, etc. or non-real time operating system such as Windows, UNIX, LINUX, etc., or as soft core realized HDL circuits embodied in an Application. Specific Integrated Circuit (ASIC) or Field Programmable Gate Array (FPGA), or as functionally equivalent discrete hardware components.

There is thus provided in accordance with the invention, a method of transistor mismatch compensation for use in digital power amplifier, the method comprising the steps of receiving a digital amplitude code representing a desired amplifier output power level, determining a predistortion correction value based on the digital amplitude code and applying the predistortion correction value to the digital amplitude code thereby compensating the output of the amplifier for transistor mismatch effects therein.

There is also provided in accordance with the invention, a method of pre-distortion for transistor mismatch compensation in a digital power amplifier, the method comprising the steps of receiving a digital amplitude code representing a desired amplifier output power level and applying a predistortion correction value determined in accordance with the digital amplitude code to a portion of the digital amplitude code corresponding to one or more amplifier transistors to be compensated for mismatch effects.

There is further provided in accordance with the invention, an apparatus for transistor mismatch compensation in a digital power amplifier comprising an input for receiving a digital amplitude code represented a desired amplifier output power level, a table coupled to the input for storing a plurality of correction values and a correction circuit operative to apply correction values output of the table to the digital amplifier code thereby compensating the output of the amplifier for transistor mismatch effects.

There is also provided in accordance with the invention, an apparatus for compensating an amplifier for transistor mismatch effects comprising an input signal for receiving a digital amplitude code represented a desired amplifier output power level, a lookup table (LUT) coupled to the input signal for storing a plurality of correction values, a correction circuit operative to apply correction values output of the table to an integer least significant bit (LSB) portion of the digital amplifier code thereby compensating the output of the amplifier for transistor mismatch effects and an output register for storing a non-compensated integer most significant bit (MSB) portion and a compensated LSB portion of the amplitude code.

There is further provided in accordance with the invention, an apparatus for compensating for device mismatch effects in a digital power amplifier (DPA) comprising a single segmented bank of amplifier transistors comprising a most significant bit (MSB) bank comprising a first plurality of devices having a first size, a least significant bit (LSB) bank comprising a second plurality of devices having a second size, a predistortion circuit operative to compensate a DPA input signal for mismatches between the MSB bank devices and the LSB bank devices to yield a compensated DPA input signal thereby, the DPA input signal comprising an LSB portion and an MSB portion and wherein compensation of the DPA input signal by the predistortion circuit is dependent on the MSB portion of the DPA input signal.

There is also provided in accordance with the invention, a method of generating a plurality of correction values for use in an amplifier transistor mismatch pre-distortion circuit, the amplifier having a segmented bank of transistors incorporating first transistors of a first size and second transistors of a second size, the method comprising the steps of determining desired first voltage steps for each of the first transistors, determining desired second voltage steps for each of the second transistors in accordance with the desired first voltage steps, measuring actual third voltage steps for the second transistors and calculating the correction values as a function of the ratio of the second voltage steps to the third voltage steps.

There is further provided in accordance with the invention, a polar radio frequency (RF) transmitter comprising means for generating a frequency command and an amplitude command in accordance with the modified TX IQ data samples, a pre-distortion circuit for compensating a digital power amplifier (DPA) for transistor mismatch effects, the pre-distortion circuit operative to receive the digital amplitude command representing a desired amplifier output power level, determine a predistortion correction value based on the digital amplitude command, apply the predistortion correction value to the digital amplitude command to generate a compensated digital amplitude command which effectively compensates the output of the DPA for transistor mismatch effects therein, a frequency synthesizer operative to generate an RF signal having a frequency in accordance with a frequency reference input and the frequency command and the digital power amplifier (DPA) operative to receive the RF signal and to generate a modulated RF output signal in proportion to the compensated amplitude command.

There is also provided in accordance with the invention, a method of device mismatch compensation for use in a radio frequency digital to analog converter (RF DAC), the method comprising the steps of receiving an input code representing a desired RF DAC output, determining a predistortion correction value based on the input code and applying the predistortion correction value to the input code thereby compensating the output of the RF DAC for device mismatch effects therein.

### BRIEF DESCRIPTION OF THE DRAWINGS

The invention is herein described, by way of example only, with reference to the accompanying drawings, wherein:

FIG. 1 is a block diagram illustrating an example prior art polar transmitter;

FIG. 2 is a block diagram illustrating a generic prior art modulator having a uniform array of conversion devices;

FIG. 3 is a block diagram illustrating a generic prior art modulator having a segmented array of conversion devices;

FIG. 4 is a schematic diagram illustrating a prior art digital to RF amplitude converter (DRAC);

FIG. 5 is a graph illustrating the effects of compression and device mismatch on the DPA output voltage function versus DPA code;

FIG. 6 is a graph illustrating example differential transfer function with MSB/LSB device mismatch and compression as a function of DPA input code in the presence of;

FIG. 7 is a block diagram illustrating an example single chip radio incorporating the device mismatch predistortion mechanism of the present invention;

FIG. 8 is a simplified block diagram illustrating an example mobile communication device incorporating the device mismatch predistortion mechanism of the present invention within one or more multiple radio transceivers;

FIG. 9 is a block diagram illustrating an example ADPLL-based polar transmitter suitable for use with the present invention and incorporating the device mismatch predistortion mechanism;

FIG. 10 is a diagram illustrating the device array structure of the DPA in more detail;

FIG. 11 is a block diagram illustrating a portion of a polar transmitter signal path incorporating the device mismatch predistortion mechanism of the present invention;

FIG. 12 is a graph illustrating the code-to-voltage slope variation due to MSB/LSB ratio device mismatch;

FIGS. 13A and 13B are graphs illustrating the spectrum of the DPA differential step size in the presence of MSB/LSB ratio mismatch and device variability;

FIG. 14 is a diagram illustrating the amplitude control word (ACW) bits connected to different size devices;

FIG. 15 is a block diagram illustrating an example device mismatch predistortion circuit of the present invention;

FIG. 16 is a graph illustrating an example ratio curve stored in the LUT for correcting device mismatch;

FIG. 17 is a graph illustrating the frequency spectrum output without device mismatch predistortion;

FIG. 18 is a zoomed in portion of the graph of FIG. 17 showing a spectral mask violation;

FIG. 19 is a graph illustrating the frequency spectrum output with device mismatch predistortion;

FIG. 20 is a zoomed in portion of the graph of FIG. 19 showing no spectral mask violation;

FIG. 21 is a graph illustrating an example ratio curve stored in the LUT for correcting device mismatch whose entries are not as accurate as than those of FIG. 16;

FIG. 22 is a graph illustrating the frequency spectrum output with device mismatch predistortion using the curve of FIG. 21; and

FIG. 23 is a zoomed in portion of the graph of FIG. 22 showing no spectral mask violation.

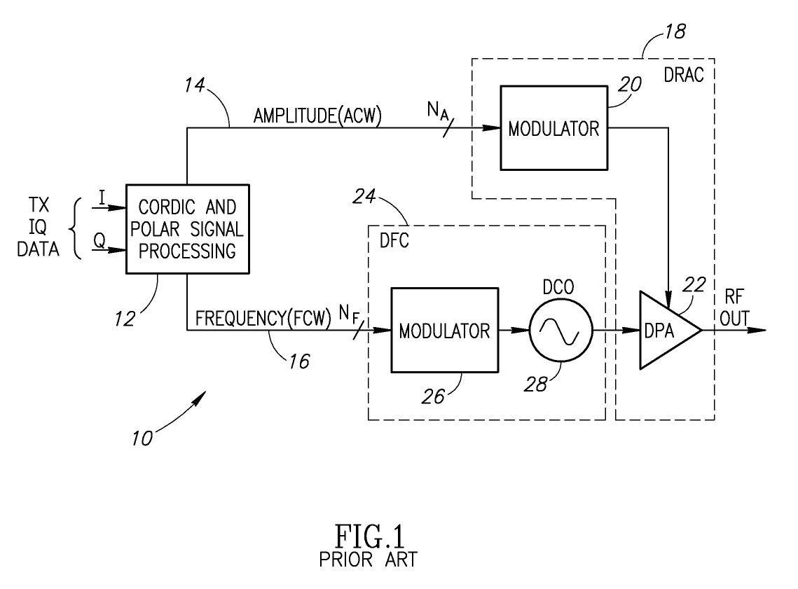

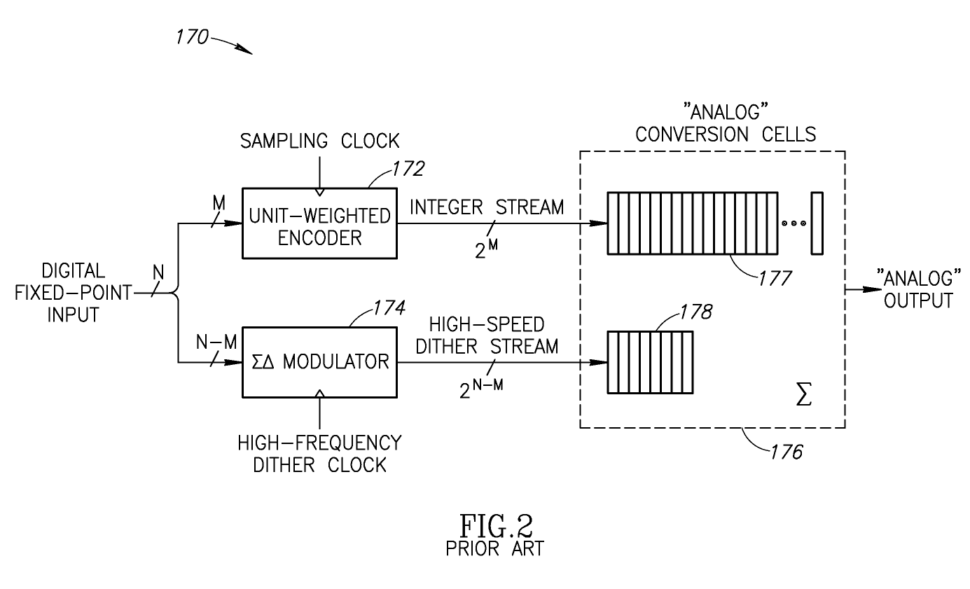

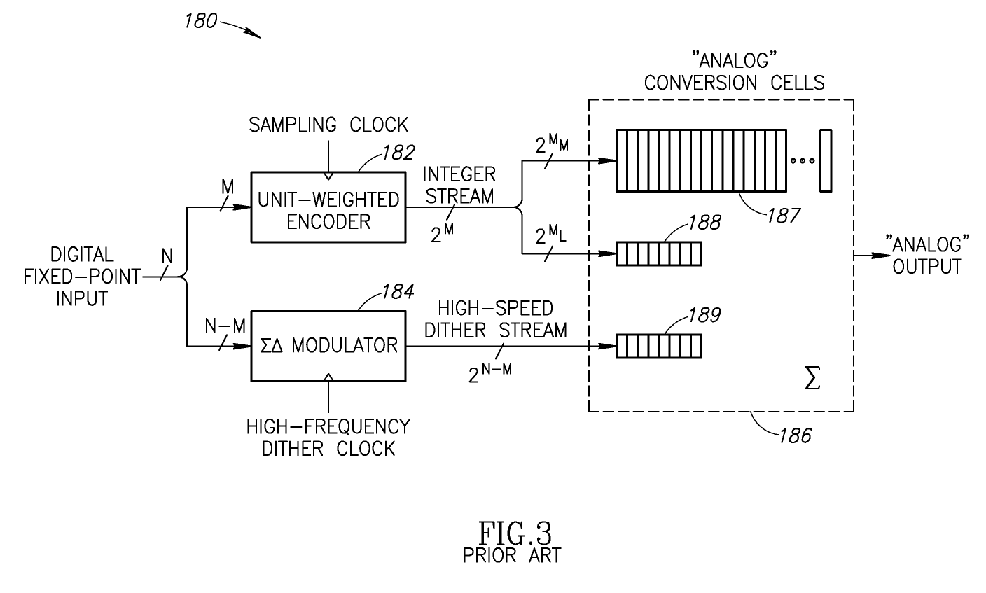

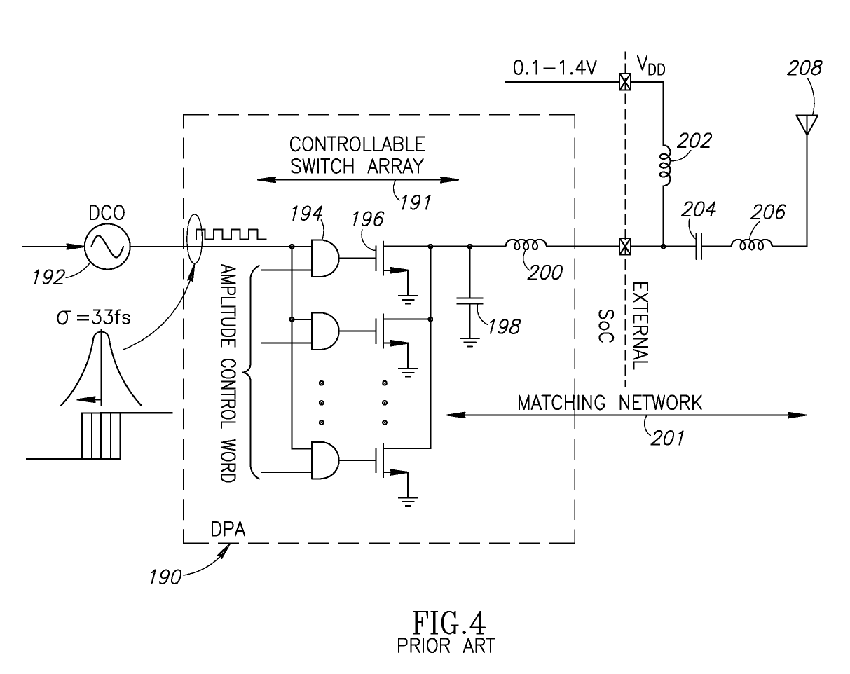

### DETAILED DESCRIPTION OF THE INVENTION

### Notation Used Throughout

The following notation is used throughout this document.

### Term Definition

AC Alternating Current
ACW Amplitude Control Word
ADC Analog to Digital Converter
ADPLL All Digital Phase Locked Loop
AM Amplitude Modulation
ASIC Application Specific Integrated Circuit
AVI Audio Video Interface
BIST Built-In Self Test
BMP Windows Bitmap
CMOS Complementary Metal Oxide Semiconductor
CORDIC COordinate Rotation DIgital Computer
CPU Central Processing Unit
DAC Digital to Analog Converter
dB Decibel
DBB Digital Baseband
DC Direct Current
DCO Digitally Controlled Oscillator
DCXO Digitally Controlled Crystal Oscillator
DEM Dynamic Element Matching
DFC Digital-to-Frequency Conversion
DNL Dynamic Non-linearity
DPA Digitally Controlled Power Amplifier
DRAC Digital to RF Amplitude Conversion
DRP Digital RF Processor or Digital Radio Processor
DSL Digital Subscriber Line
DSP Digital Signal Processor
DTX Transmit Data Processing
EDGE Enhanced Data Rates for GSM Evolution
EEPROM Electrically Erasable Programmable Read Only Memory
EPROM Erasable Programmable Read Only Memory
EVM Error Vector Magnitude
FCC Federal Communications Commission
FCW Frequency Command Word
FIB Focused Ion Beam
FM Frequency Modulation
FPGA Field Programmable Gate Array
FREF Frequency Reference
GMSK Gaussian Minimum Shift Keying
GPRS General Packet Radio Service
GPS Global Positioning System
GSM Global System for Mobile communications
HB High Band
HDL Hardware Description Language
I/F Interface
IC Integrated Circuit
IEEE Institute of Electrical and Electronics Engineers
IIR Infinite Impulse Response
JPG Joint Photographic Experts Group
LAN Local Area Network
LB Low Band
LDO Low Drop Out
LO Local Oscillator
LPF Low Pass Filter
LSB Least Significant Bit
LUT Look Up Table
MAC Media Access Control
MAP Media Access Protocol
MOS Metal Oxide Semiconductor
MP3 MPEG-1 Audio Layer 3
MPG Moving Picture Experts Group
MSB Most Significant Bit
MUX Multiplexer
NMOS n-channel Metal Oxide Semiconductor
OTW Oscillator Tuning Word
PA Power Amplifier
PAN Personal Area Network
PC Personal Computer
PCI Personal Computer Interconnect
PCS Personal Communications Service
PDA Personal Digital Assistant
PE Phase Error
PHE Phase Error
PLL Phase Locked Loop
PM Phase Modulation
PNA Personal Navigation Assistant
PPA Pre-Power Amplifier
PSD Power Spectral Density
PSF Pulse Shaping Filter
QoS Quality of Service
RAM Random Access Memory
RAT Radio Access Technology
RF Radio Frequency
RFBIST RF Built-In Self Test
RMS Root Mean Squared
ROM Read Only Memory
SAM Sigma-Delta Amplitude Modulation
SAW Surface Acoustic Wave
SCO Synchronous Connection-Oriented
SIM Subscriber Identity Module
SoC System on Chip
SPI Serial Peripheral Interface
SRAM Static Read Only Memory
SYNTH Synthesizer
TDC Time to Digital Converter
TDD Time Division Duplex
TV Television
UGS Unsolicited Grant Services
USB Universal Serial Bus
UWB Ultra Wideband
VCO Voltage Controlled Oscillator
WCDMA Wideband Code Division Multiple Access
WiFi Wireless Fidelity
WiMAX Worldwide Interoperability for Microwave Access
WiMedia Radio platform for UWB
WLAN Wireless Local Area Network
WMA Windows Media Audio
WMAN Wireless Metropolitan Area Network
WMV Windows Media Video
WPAN Wireless Personal Area Network
XOR Exclusive Or
ZOH Zero Order Hold

### DETAILED DESCRIPTION OF THE INVENTION

The present invention is a novel and useful apparatus for and method of predistortion compensation of device (e.g., transistor) mismatch in a digital power amplifier (DPA). The device mismatch predistortion mechanism of the present invention addresses the problem of matching between two types/sizes of unit weighted transistors, whereby mismatched transistors cause degradation in wideband noise.

The invention provides a digital predistortion mechanism which functions to pre-distort the mismatch ratio based a characterization data table created a priori enabling a polar transmitter to meet output spectrum and error vector magnitude (EVM) requirements of the particular modern wideband wireless standard, such as GSM, 3G WCDMA, etc.

The device mismatch predistortion mechanism described herein is suitable for use in any application implementing an RF digital to analog converter (DAC), e.g., DPA, etc., employing polar modulation that utilizes multiple types of binary weighted devices or transistors to achieve the desired amplitude path resolution.

Although the device mismatch predistortion mechanism is applicable to numerous wireless communication standards and can be incorporated in numerous types of wireless or wired communication devices such a multimedia player, mobile station, cellular phone, PDA, DSL modem, WPAN device, etc., it is described in the context of a digital RF processor (DRP) based transmitter that may be adapted to comply with a particular wireless communications standard such as GSM, Bluetooth, EDGE, WCDMA, WLAN, WiMax, etc. It is appreciated, however, that the invention is not limited to use with any particular communication standard and may be used in optical, wired and wireless applications. The invention is primarily intended for use in applications employing a polar transmitter where it is desired to reduce the phase and amplitude modulation bandwidth of the polar modulation.

Note that throughout this document, the term communications device is defined as any apparatus or mechanism adapted to transmit, receive or transmit and receive data through a medium. The term communications transceiver or communications device is defined as any apparatus or mechanism adapted to transmit and receive data through a medium. The communications device or communications transceiver may be adapted to communicate over any suitable medium, including wireless or wired media. Examples of wireless media include RF, infrared, optical, microwave, UWB, Bluetooth, WiMAX, WiMedia, WiFi, or any other broadband medium, etc. Examples of wired media include twisted pair, coaxial, optical fiber, any wired interface (e.g., USB, Firewire, Ethernet, etc.). The term Ethernet network is defined as a network compatible with any of the IEEE 802.3 Ethernet standards, including but not limited to 10 Base-T, 100 Base-T or 1000 Base-T over shielded or unshielded twisted pair wiring. The terms communications channel, link and cable are used interchangeably. The notation DRP is intended to denote either a Digital RF Processor or Digital Radio Processor. References to a Digital RF Processor infer a reference to a Digital Radio Processor and vice versa.

The term multimedia player or device is defined as any apparatus having a display screen and user input means that is capable of playing audio (e.g., MP3, WMA, etc.), video (AVI, MPG, WMV, etc.) and/or pictures (JPG, BMP, etc.). The user input means is typically formed of one or more manually operated switches, buttons, wheels or other user input means. Examples of multimedia devices include pocket sized personal digital assistants (PDAs), personal navigation assistants (PNAs), personal media player/recorders, cellular telephones, handheld devices, and the like.

References to devices or transistors are intended to include not only transistors but any type of conversion device or analog quantity, such as capacitance, voltage, current, resistance, frequency, power, etc. Examples of conversion devices include, but are not limited to, transistors, varactors, etc.

References to MSB devices or transistors are intended to refer to Nx sized devices or transistors (where N=2, 4, 8, etc.). References to LSB devices or transistors are intended to refer to 1× sized devices or transistors.

Some portions of the detailed descriptions which follow are presented in terms of procedures, logic blocks, processing, steps, and other symbolic representations of operations on data bits within a computer memory. These descriptions and representations are the means used by those skilled in the data processing arts to most effectively convey the substance of their work to others skilled in the art. A procedure, logic block, process, etc., is generally conceived to be a self-consistent sequence of steps or instructions leading to a desired result. The steps require physical manipulations of physical quantities. Usually, though not necessarily, these quantities take the form of electrical or magnetic signals capable of being stored, transferred, combined, compared and otherwise manipulated in a computer system. It has proven convenient at times, principally for reasons of common usage, to refer to these signals as bits, bytes, words, values, elements, symbols, characters, terms, numbers, or the like.

It should be born in mind that all of the above and similar terms are to be associated with the appropriate physical quantities they represent and are merely convenient labels applied to these quantities. Unless specifically stated otherwise as apparent from the following discussions, it is appreciated that throughout the present invention, discussions utilizing terms such as ‘processing,’ ‘computing,’ ‘calculating,’ ‘determining,’ ‘displaying’ or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The invention can take the form of an entirely hardware embodiment, an entirely software embodiment or an embodiment containing a combination of hardware and software elements. In one embodiment, a portion of the mechanism of the invention is implemented in software, which includes but is not limited to firmware, resident software, object code, assembly code, microcode, etc.

Furthermore, the invention can take the form of a computer program product accessible from a computer-usable or computer-readable medium providing program code for use by or in connection with a computer or any instruction execution system. For the purposes of this description, a computer-usable or computer readable medium is any apparatus that can contain, store, communicate, propagate, or transport the program for use by or in connection with the instruction execution system, apparatus, or device, e.g., floppy disks, removable hard drives, computer files comprising source code or object code, flash semiconductor memory (USB flash drives, etc.), ROM, EPROM, or other semiconductor memory devices.

### Single Chip Radio

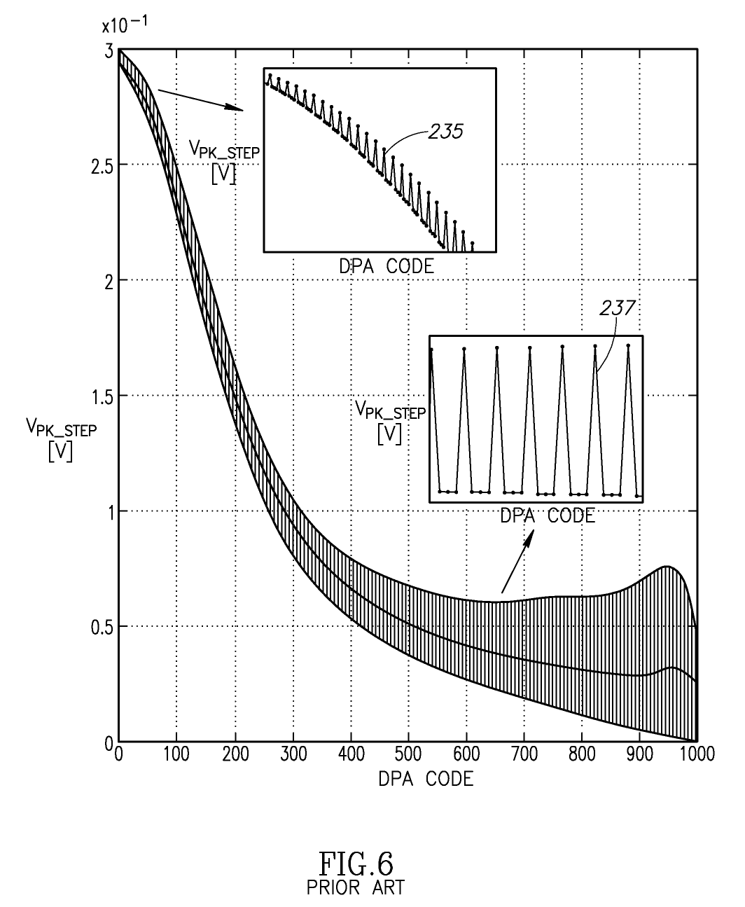

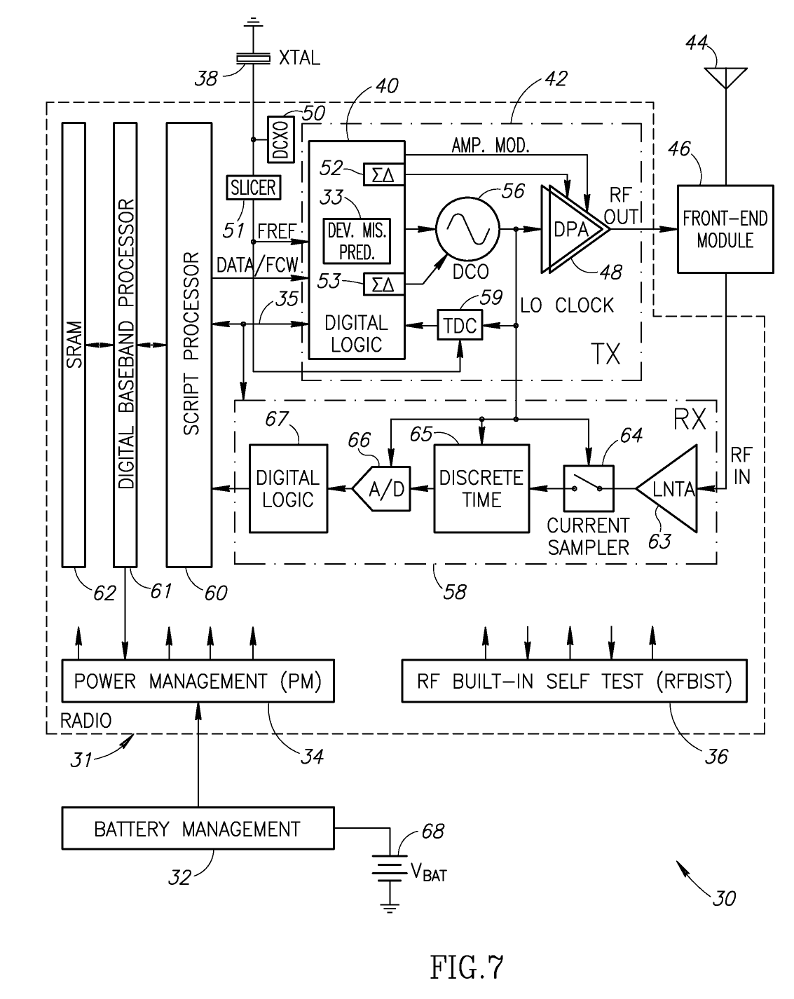

A block diagram illustrating an example single chip radio incorporating the device mismatch predistortion mechanism of the present invention is shown in FIG. 7. For illustration purposes, the transmitter may be is adapted for any desired cellular standard, e.g., WCDMA, GSM/EDGE, etc. It is appreciated, however, that one skilled in the communication arts can adapt the transmitter illustrated herein to other modulations and communication standards as well without departing from the spirit and scope of the present invention.

The radio circuit, generally referenced 30, comprises a single chip radio integrated circuit (IC) 31 coupled to a crystal 38, front end module (FEM) 46, antenna 44 and battery management circuit 32 connected to a battery 68. The radio chip 31 comprises a script processor 60, digital baseband (DBB) processor 61, memory 62 (e.g., static RAM), TX block 42, RX block 58, digitally controlled crystal oscillator (DCXO) 50, slicer 51, power management unit 34 and RF built-in self test (BIST) 36. The TX block comprises high speed and low speed digital logic block 40 including device mismatch predistortion block 33, ΣΔ modulators 52, 53, digitally controlled oscillator (DCO) 56, TDC 59 and digitally controlled power amplifier (DPA) or pre-power amplifier (PPA) 48. The ADPLL and transmitter generate various radio frequency signals. The RX block comprises a low noise transconductance amplifier 63, current sampler 64, discrete time processing block 65, analog to digital converter (ADC) 66 and digital logic block 67 for the digital processing of the recovered signal in the receiver.

In accordance with the invention, the radio comprises a device mismatch predistortion block 33 operative to predistort the device mismatch using a data table determined a priori or adaptively in real time. The device mismatch predistortion block may be implemented in hardware, software or a combination of hardware and software. Alternatively, the device mismatch predistortion block may be implemented as a software task on the script processor.

The structure presented herein has been used to develop multiple generations of a Digital RF Processor (DRP) for single-chip Bluetooth, GSM, GSM/EDGE and WCDMA radios which may be realized in 130 nm, 90 nm, 65 nm, 45 nm digital CMOS process technologies, for example. The common architecture is highlighted in FIG. 7 with features specific to the cellular radio. The all digital phase locked loop (ADPLL) based transmitter employs a polar architecture with all digital phase/frequency and amplitude modulation paths. The receiver employs a discrete-time architecture in which the RF signal is directly sampled and processed using analog and digital signal processing techniques.

A key component is the digitally controlled oscillator (DCO) 56, which avoids any analog tuning controls. A digitally-controlled crystal oscillator (DCXO) generates a high-quality base-station-synchronized frequency reference such that the transmitted carrier frequencies and the received symbol rates are accurate to within 0.1 ppm. Digital logic built around the DCO realizes an all-digital PLL (ADPLL) that is used as a local oscillator for both the transmitter and the receiver. The polar transmitter architecture utilizes the wideband direct frequency modulation capability of the ADPLL and a digitally controlled power amplifier (DPA) 48 for the amplitude modulation. The DPA operates in near-class-E mode and uses an array of nMOS transistor switches to regulate the RF amplitude and acts as a digital-to-RF amplitude converter (DRAC). It is followed by a matching network and an external front-end module 46, which comprises a power amplifier (PA), a transmit/receive switch for the common antenna 44 and RX surface acoustic wave (SAW) filters. Fine amplitude resolution is achieved through high-speed ΣΔ dithering of the DPA nMOS transistors.

The receiver 58 employs a discrete-time architecture in which the RF signal is directly sampled at the Nyquist rate of the RF carrier and processed using analog and digital signal processing techniques. The transceiver is integrated with a script processor 60, dedicated digital base band processor 61 (i.e. ARM family processor or DSP) and SRAM memory 62. The script processor handles various TX and RX calibration, compensation, sequencing and lower-rate data path tasks and encapsulates the transceiver complexity in order to present a much simpler software programming model.

The frequency reference (FREF) is generated on-chip by a 26 MHz (could be 38.4 MHz or other) digitally controlled crystal oscillator (DCXO) 50 coupled to slicer 51. An integrated power management (PM) system is connected to an external battery management circuit 32 that conditions and stabilizes the supply voltage. The PM comprises multiple low drop out (LDO) regulators that provide internal supply voltages and also isolate supply noise between circuits. The RF built-in self-test (RFBIST) 36 performs autonomous phase noise and modulation distortion testing, and various loopback configurations for transmitter and receiver tests. The transceiver is integrated with the digital baseband and SRAM in a complete system-on-chip (SoC) solution. Almost all the clock signals on this SoC are derived from and are synchronous to the RF oscillator clock. This helps to reduce susceptibility to the noise generated through clocking of the massive digital logic.

The transmitter comprises a polar architecture in which the amplitude and phase/frequency modulations are implemented in separate paths. Transmitted symbols generated in the digital baseband (DBB) processor are first pulse-shape-filtered in the Cartesian coordinate system. The filtered in-phase (I) and quadrature (Q) samples are then converted through a CORDIC algorithm into amplitude and phase samples of the polar coordinate system. The phase is then differentiated to obtain frequency deviation. The polar signals are subsequently conditioned through signal processing to sufficiently increase the sampling rate in order to reduce the quantization noise density and lessen the effects of the modulating spectrum replicas.

A more detailed description of the operation of the ADPLL can be found in U.S. Patent Publication No. 2006/0033582A1, published Feb. 16, 2006, to Staszewski et al., entitled “Gain Calibration of a Digital Controlled Oscillator,” U.S. Patent Publication No. 2006/0038710A1, published Feb. 23, 2006, to Staszewski et al., entitled “Hybrid Polar/Cartesian Digital Modulator” and U.S. Pat. No. 6,809,598, to Staszewski et al., entitled “Hybrid Of Predictive And Closed-Loop Phase-Domain Digital PLL Architecture,” all of which are incorporated herein by reference in their entirety.

### Mobile Device/Cellular Phone/PDA/PNA

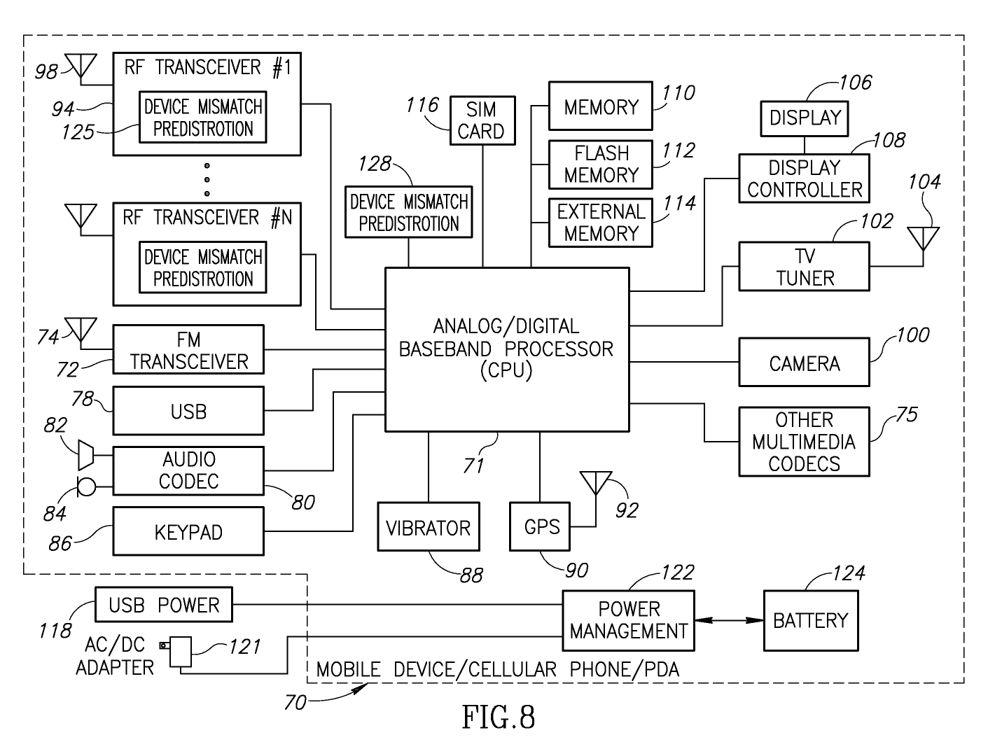

A simplified block diagram illustrating an example mobile communication device incorporating the device mismatch predistortion mechanism of the present invention within multiple radio transceivers is shown in FIG. 8. Note that the mobile device may comprise any suitable wired or wireless device such as multimedia player, mobile communication device, cellular phone, smartphone, PDA, PNA, Bluetooth device, etc. For illustration purposes only, the device is shown as a mobile device, such as a cellular phone. Note that this example is not intended to limit the scope of the invention as the device mismatch predistortion mechanism of the present invention can be implemented in a wide variety of communication devices.

The mobile device, generally referenced 70, comprises a baseband processor or CPU 71 having analog and digital portions. The mobile device may comprise a plurality of RF transceivers 94 and associated antennas 98. RF transceivers for the basic cellular link and any number of other wireless standards and Radio Access Technologies (RATs) may be included. Examples include, but are not limited to, Global System for Mobile Communication (GSM)/GPRS/EDGE 3G; WCDMA; WiMAX for providing WiMAX wireless connectivity when within the range of a WiMAX wireless network; Bluetooth for providing Bluetooth wireless connectivity when within the range of a Bluetooth wireless network; WLAN for providing wireless connectivity when in a hot spot or within the range of an ad hoc, infrastructure or mesh based wireless LAN network; near field communications; UWB; etc. One or more of the RF transceivers may comprise additional antennas to provide antenna diversity which yields improved radio performance. The mobile device may also comprise internal RAM and ROM memory 110, Flash memory 112 and external memory 114.

Several user-interface devices include microphone(s) 84, speaker(s) 82 and associated audio codec 80 or other multimedia codecs 75, a keypad 86 for entering dialing digits and for other controls and inputs, vibrator 88 for alerting a user, camera and related circuitry 100, a TV tuner 102 and associated antenna 104, display(s) 106 and associated display controller 108 and GPS receiver 90 and associated antenna 92. A USB or other interface connection 78 (e.g., SPI, SDIO, PCI, etc.) provides a serial link to a user's PC or other device. An FM transceiver 72 and antenna 74 provide the user the ability to listen to FM broadcasts as well as the ability to transmit audio over an unused FM station at low power, such as for playback over a car or home stereo system having an FM receiver. SIM card 116 provides the interface to a user's SIM card for storing user data such as address book entries, user identification, etc.

The RF transceivers 94 also comprise the device mismatch predistortion mechanism 125 of the present invention. Alternatively (or in addition to), the device mismatch predistortion mechanism may be implemented as a task 128 executed by the baseband processor 71. The device mismatch predistortion blocks 125, 128 are adapted to implement the device mismatch predistortion mechanism of the present invention as described in more detail infra. In operation, the device mismatch predistortion mechanism may be implemented as hardware, software or as a combination of hardware and software. Implemented as a software task, the program code operative to implement the device mismatch predistortion mechanism of the present invention is stored in one or more memories 110, 112 or 114 or local memories within the baseband. Portable power is provided by the battery 124 coupled to power management circuitry 122. External power is provided via USB power 118 or an AC/DC adapter 121 connected to the battery management circuitry 122, which is operative to manage the charging and discharging of the battery 124.

### ADPLL Based Polar Transmitter

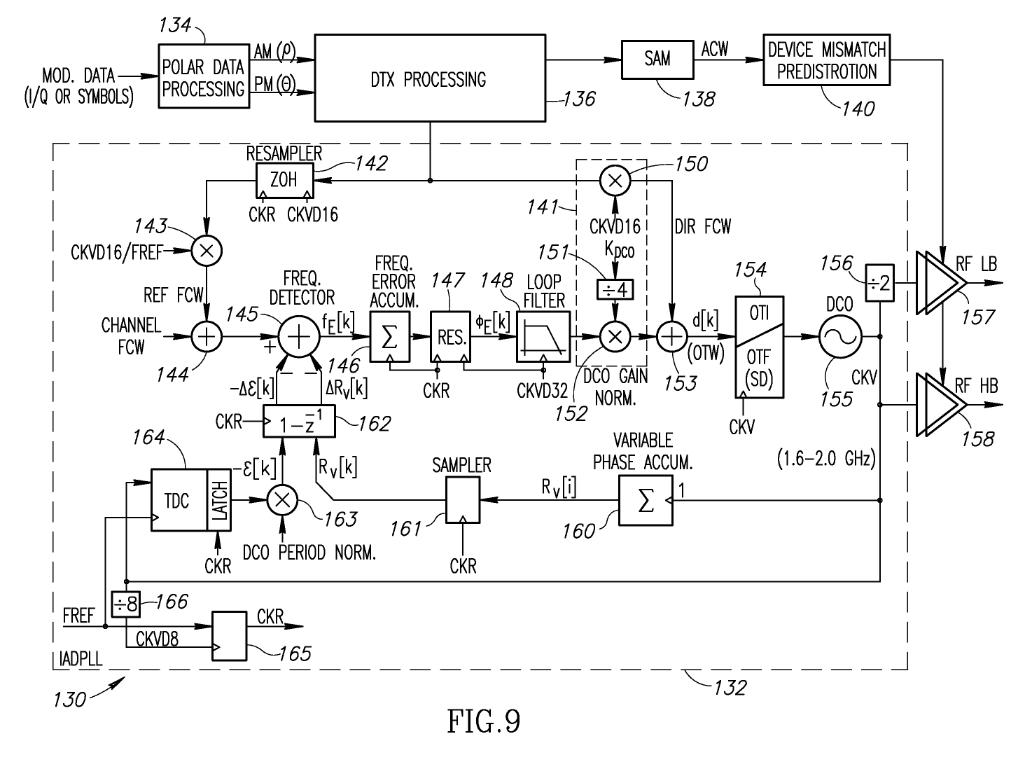

A block diagram of an iADPLL used in the radio of FIG. 7 and suitable for use with the device mismatch predistortion mechanism of the present invention is shown in FIG. 9. For illustration purposes only, the transmitter of the present embodiment is adapted for the GSM/EDGE cellular standard. It is appreciated, however, that one skilled in the communication arts can adapt the transmitter illustrated herein to other modulations and communication standards as well without departing from the spirit and scope of the present invention.

A more detailed description of the operation of an ADPLL can be found in U.S. Patent Publication No. 2006/0033582A1, published Feb. 16, 2006, to Staszewski et al., entitled “Gain Calibration of a Digital Controlled Oscillator,” U.S. Patent Publication No. 2006/0038710A1, published Feb. 23, 2006, to Staszewski et al., entitled “Hybrid Polar/Cartesian Digital Modulator” and U.S. Pat. No. 6,809,598, to Staszewski et al., entitled “Hybrid Of Predictive And Closed-Loop Phase-Domain Digital PLL Architecture,” all of which are incorporated herein by reference in their entirety.

A more detailed description of the operation of the iADPLL can be found in U.S. application Ser. No. 12/022,931, to Waheed et al., entitled “Interpolative All-Digital Phase Locked Loop,” incorporated herein by reference in its entirety.

A description of the iADPLL, generally referenced 130, including the frequency/phase modulation path is provided herein below. The core of the IADPLL is a digitally controlled oscillator (DCO) 155 adapted to generate the RF oscillator clock CKV. The oscillator core (not shown) operates at twice the 1.6-2.0 GHz high frequency band or four times the 0.8-1.0 GHz low frequency band. The output of the DCO is then divided for precise generation of RX quadrature signals, and for use as the transmitter's carrier frequency. For GSM/EDGE transceivers, a single DCO is shared between transmitter and receiver and is used for both the high frequency bands (HB) and the low frequency bands (LB). For modem 3G (WCDMA) or other duplex transmission systems, however, separate local oscillators might be needed to supply TX and RX carrier frequencies.

A digitally controlled oscillator (DCO) 155 lies at the heart of the interpolated all-digital PLL (iADPLL) frequency synthesizer. It deliberately avoids any analog tuning voltage controls and is realized as an ASIC cell with truly digital inputs and outputs. The DCO comprises tunable switchable varactor elements, cross-coupled pairs of NMOS transistors and a biasing circuit. The DCO varactors may be realized as n-poly/n-well MOS capacitor (MOSCAP) devices that operate in the flat regions of their C-V curves. Current advanced CMOS process lithography allows creation of extremely small-size but well-controlled varactors. The switchable capacitance of the finest differential TB varactor is in tens of attofarads. This resolution, however, is still too coarse for wireless applications and requires high-speed ΣΔ dithering to enhance the time-averaged frequency resolution. The output of the DCO is input to the RF high band power amplifier 158. It is also input to the RF low band power amplifier 157 after divide by two in divider 156.

In case of transmit modulation, the symbols (for example GSM, EDGE) or chips (for example WCDMA.), in the form of in-phase and quadrature data streams are received from the digital baseband (DBB) circuit (not shown). The GSM symbols are passed through a pulse-shaping filter (PSF) within processor 134 whose output is upsampled and interpolated in transmit data (DTX) processing circuit 136 and then passed to the iADPLL after differentiation at the CKVD16 clock rate. CKV is the iADPLL RF output digital variable clock in case of high bands (HB>1 GHz) or twice the RF output clock in case of low band (LB<1 GHz).

For the case of EDGE, WCDMA, etc. the complex modulation I/Q data streams are fed to a COordinate Rotation DIgital Computer (CORDIC) within processor 134, which converts it from Cartesian to polar representation. The amplitude modulation signal is passed through sigma-delta amplitude (SAM) signal processing block 138 and a device mismatch predistortion block 140 (operative to implement the device mismatch predistortion mechanism of the present invention) before they are passed onto the on-chip digital pre-power amplifier (DPA) 157, 158, while the phase modulation output of the cordic is passed to the iADPLL 132 (after the necessary interpolation and signal processing) which performs the phase modulation of the DCO.

Under normal modulation conditions, the iADPLL digitally controls the DCO to produce a stable variable clock (CKV) in the targeted RF frequency band. In the feedback path, CKV is used for phase detection and reference retiming. The time to digital phase conversion in the feedback is achieved using a TDC inverter chain 164.

The channel and data frequency control words are in the frequency command word (FCW) format, which is defined as the fractional frequency division ratio N, with a fine frequency resolution limited only by the FCW word length. For example, with 24 fractional FCW bits, the frequency granularity using a 38.4 MHz reference frequency is 38.4 MHz/2²⁴=2.29 Hz. In this embodiment, the direct point frequency injection is at CKVD16 (which is 1×HB/2×LB channel frequency divided by 16, i.e. CKVD16=fᵥ/16) rate, so the possible DCO frequency resolution is in the range of 6˜7.5 Hz

$$( computed as \frac{{f}_{v} / 16}{{2}^{24}} ) .$$

The expected variable frequency fᵥ at the DCO output is related to the reference frequency f_{R} by the frequency command word (FCW).

$$F C W [ k ] ≡ \frac{E ( {f}_{V} [ k ] )}{{f}_{R}} \qquad ( 3 )$$

The FCW is time variant and is allowed to change with every cycle T_{R}=1/f_{R} of the frequency reference clock. With W_{F}=24 the word length of the fractional part of FCW, the ADPLL provides fine frequency control with 1.5 Hz accuracy, according to:

$$Δ {f}_{res} = \frac{{f}_{R}}{{2}^{{W}_{F}}} \qquad ( 4 )$$

The number of integer bits W_{I}=8 has been chosen to fully cover the GSM/EDGE and partial WCDMA band frequency range of f_{V}=1,600−2,000 MHz with an arbitrary reference frequency f_{R}≧8 MHz.

The iADPLL operates in a digitally-synchronous fixed-point phase domain as follows. The variable phase accumulator 160 determines the variable phase R_{V}[i] by counting the number of rising clock transitions of the DCO oscillator clock CKV as expressed below.

$${R}_{V} [ i ] = {\sum }_{l = 0}^{i} 1 \qquad ( 5 )$$

The index i indicates the DCO edge activity. The variable phase R_{V}[i] is sampled via sampler 161 to yield sampled FREF variable phase R_{V}[k], where k is the index of the FREF edge activity. The sampled FREF variable phase R_{V}[k] is fixed-point concatenated with the normalized time-to-digital converter (TDC) 164 output ε[k]. The TDC measures and quantizes the time differences between the frequency reference FREF and the DCO clock edges. The sampled differentiated (via block 162) variable phase is subtracted from the frequency command word (FCW) by the digital frequency detector 145. The frequency error f_{E}[k] samples

f_{E}[k]=FCW−[(R_{V}[k]−ε[k])−(R_{V}[k−1]−ε[k−1])] (6)

are accumulated via the frequency error accumulator 146 to create the phase error φ_{E}[k] samples

$${φ}_{E} [ k ] = {\sum }_{l = 0}^{k} {f}_{E} [ k ] \qquad ( 7 )$$

which are then filtered by a fourth order IIR loop filter 148 and scaled by a proportional loop attenuator α. A parallel feed with coefficient ρ adds an integrated term to create type-II loop characteristics which suppress the DCO flicker noise.

The loop behavior due to its digital nature is independent of process, voltage and temperature variations. The FREF retiming quantization error ε[k] is determined by the time-to-digital converter (TDC) 164 and the DCO period normalization multiplier 163. The TDC is built as a simple array of cascaded inverter delay elements and flip-flops, which produces time conversion resolution finer than 25 ps in the design process.

The IIR filter is a cascade of four single stage filters, each satisfying the following equation:

y[k]=(1−λ)·y[k−1]+λ·x[k] (8)

wherein

x[k] is the current input;

y[k] is the current output;

k is the time index;

λ is the configurable coefficient;

The 4-pole IIR loop filter attenuates the reference and TDC quantization noise with an 80 dB/dec slope, primarily to meet the GSM/EDGE spectral mask requirements at 400 kHz offset. The filtered and scaled phase error samples are then multiplied by the DCO gain K_{DCO} normalization factor f_{R}/\hat{K}_{DCO} via multiplier 152, where f_{R} is the reference frequency and \hat{K}_{DCO} is the DCO gain estimate, to make the loop characteristics and modulation independent from K_{DCO}. The modulating data is injected into two points of the iADPLL for direct frequency modulation, via adders 144 and 153. A hitless gear-shifting mechanism for the dynamic loop bandwidth control serves to reduce the settling time. It changes the loop attenuator α several times during the frequency locking while adding the (α₁/α₂−1)φ₁ dc offset to the phase error, where indices 1 and 2 denote before and after the event, respectively. Note that φ₁=φ₂, since the phase is to be continuous.

The frequency reference FREF is input to the retimer 165 and provides the clock for the TDC 162. The FREF input is resampled by the RF oscillator clock CKV via retimer block 165 which may comprise a flip flop or register clocked by the reference frequency FREF. The resulting retimed clock (CKR) is distributed and used throughout the system. This ensures that the massive digital logic is clocked after the quiet interval of the phase error detection by the TDC. Note that in the example embodiment described herein, the ADPLL is a discrete-time sampled system implemented with all digital components connected with all digital signals.

It is noted that the two clock domains, FREF and DCO, are not entirely synchronous and it is difficult to physically compare the two digital phase values without having to face meta-stability problems. During the frequency acquisition, their edge relationship is not known and during the phase lock the edges will exhibit rotation if the fractional FCW is non-zero. Consequently, the digital word phase comparison is performed in the same clock domain. The synchronous operation is achieved by oversampling the FREF clock using a higher rate DCO derived clock (typically CKVD8) in reference retiming circuit 165. The resulting retimed CKR clock is thus stripped of the FREF timing information and is used throughout the system. This ensures that the massive digital logic is clocked after the quiet interval of the phase error detection by the TDC.

The main advantage of representing the phase information in fixed point digital numbers is that, after the conversion it cannot be further corrupted by noise. Consequently, the phase detector could be simply realized as an arithmetic subtractor that performs an exact digital operation. Thus, having a single conversion place, where the continuously valued clock transition edge delay is quantized within the TDC, the susceptibility to noise and quantization errors is minimized and well controlled. It is emphasized that it is advantageous to operate in the phase domain for several reasons. Firstly, the phase detector used is not a conventional correlative multiplier generating reference spurs. DRP architecture uses an arithmetic subtractor 145, which does not introduce any spurs into the loop. Secondly, the dynamic range of the phase error could be made arbitrarily large simply by the increasing word length of the phase/frequency accumulators. Conventional three state phase/frequency detectors are typically limited to only ±27π of the compare rate. Thirdly, the phase domain operation is more amenable to digital implementations, contrary to the conventional approach.

As shown in FIG. 9, the oscillating frequency deviation Δf is dynamically controlled by directly modulating the DCO frequency in a feed-forward manner. The iADPLL loop compensates by effectively removing the loop dynamics from the modulating transmit path (using the reference modulation injection). The remainder of the loop, including all error sources, operates under the normal closed-loop regime. This method is similar to the conventional two-point direct modulation scheme but because of the digital nature, it is exact and does not require any analog component matching, except for the DCO gain K_{DCO}=Δf/ΔOTW calibration, which is achieved in using a robust hybrid stochastic-gradient algorithm implemented in digital domain, where the oscillator tuning word (OTW) is analogous to the voltage tuning of a VCO.

The fixed-point frequency modulating data FCW is resampled in resampler 142 by the reference frequency f_{R} and normalized in multiplier 143 to the value of iADPLL DCO injection frequency fᵥ/16. Using the direct injection of the normalized FCW directly at the DCO impacts the oscillating frequency. The PLL loop will attempt to correct this perceived frequency perturbation integrated over the update period of 1/f_{R}, which is then interpolated to the iADPLL operational frequency of in resampling interpolator 147. This corrective action is compensated by the other (compensating) reference feed that is integrated by the reference phase accumulator. If the estimated DCO gain is accurate, i.e., \hat{K}_{DCO}≅K_{DCO}, then the loop response to the modulation is flat from dc to f_{V}/64 (or half of the iADPLL operational frequency f_{V}/32). The immediate and direct DCO frequency control, made possible by accurate prediction of the DCO transfer function, is combined with the phase compensation of the PLL loop response. The two factors constitute the hybrid of predictive/closed PLL loop modulation method.

An advantage of using a direct point injection rate (e.g., channel frequency divided by 16) is that the phase modulation can be presented to the DCO with a finer resolution. For example, the phase modulation in GSM has a bandwidth of 200 kHz, while for a polar TX, in EDGE mode the phase modulation bandwidth is approximately 2.0 MHz (LB) and 1.0 MHz (HB). The CKVD16 rate corresponds to an injection frequency range of 103-124 MHz, which is at least three times higher than an FREF of 38.4 MHz, and four times higher than an FREF of 26 MHz. This implies that the phase modulation data update using a CKVD16 rate will be 3 to 4 times finer than the FREF rate used in the previous generations of ADPLL.

Furthermore, the data injection into the DCO comprises integer and fractional parts. The injection rate creates an effective zero order hold (ZOH) at resampler 142. The ZOH operation does not provide a large attenuation to the sampling replicas, which is only 13 dB lower for second harmonics and approximately 17 dB for third harmonics. As CKVD16 frequency is much higher than FREF, these replicas are correspondingly at 3 to 4 times higher frequency for CKVD16 (>100 MHz) vs. FREF (26-38.4 MHz). The DCO phase noise beyond the flicker corner of 1-2 MHz has a 20 dB/decade slope, which implies that the residual sampling replicas after ZOH 142 sync filtering will receive an additional attenuation of 12 dB using a CKVD16 injection rate as compared to FREF. In short, use of CKVD16 for direct point phase modulation injection results in pushing any sampling replicas to frequencies greater than 100 MHz from the carrier, where they are greatly attenuated by the DCO phase noise and the spectral skirt of the loop filter. Essentially these signal processing spurs are below the noise floor and cannot be seen in simulations or measurements.

Another benefit of using CKVDx, where x=16 or 8 for direct point injection is that the quality of phase modulation injection becomes independent of the FREF frequency. The same iADPLL when used with different FREFs, e.g., 26, 38.4 or 52 MHz, exhibit the same direct point injection fidelity. Note, however, that there are other noise scaling terms that are impacted by the FREF frequency change. The iADPLL loop filters, modulation injection rates etc., however, maintain their resolution across multiple possible reference frequencies.

It has been observed in previous versions of the ADPLL that the current spikes caused by clocking of bulk of the logic can be a source of spurious emissions. This is especially true for highly integrated transceivers targeted using DRP technology. For the iADPLL, a significant part of the loop filter and DCO interface logic executes in the LO derived clock domain. Since most of these frequencies are chosen to be higher than FREF, any such spurious products will have a larger intra-spur distance than FREF. For example, using CKVD32, the spurs (if present) will be 52-62 MHz apart as compared to FREF frequencies. In retrospect, the current spikes due to the modulation injection rate into DCO have the highest impact, as the rush current to the boundary level-shifters might be supplied by the same LDO supply regulator, which powers the DCO. The most critical among these spurs are the ones that appear in the corresponding GSM/EDGE RX band during transmission. The widest GSM RX band is 65 MHz, and using CKVD16 at the interface results in at most one spur appearing in the RX band due to these parasitic supply regulation issues. Therefore, the use of a higher direct-point injection frequency (>100 MHz) theoretically reduces the possibility of multiple spurs in the RX band.

### Device Mismatch Predistortion Mechanism

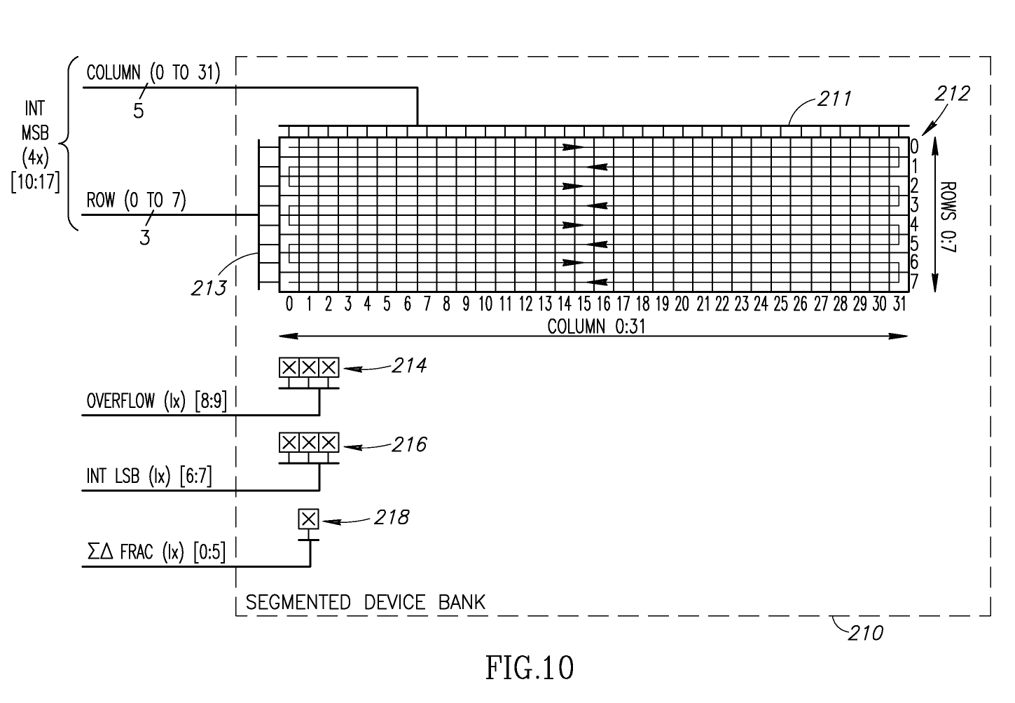

A diagram illustrating the device array structure of the DPA in more detail is shown in FIG. 10. The segmented device bank, generally referenced 210, is a key component of the DPA circuit responsible for applying the amplitude modulation to the output of the DCO. The device bank 210 comprises an array 212 of 256 integer MSB devices of 4× size arranged as eight rows (addressed by 3-bit address bus 213) by 32 columns (addressed by 5-bit address 211), three overflow devices 214 of 1× size, three integer LSB devices 216 of 1× size and one sigma-delta device 218 of 1× size.

In the example embodiment presented herein, the segmented device bank uses two different device (i.e. transistor) sizes. The 4× (or MSB) size is used in the matrix structure of 256 transistors and the 1× (or LSB) size is used for the finest Nyquest resolution (integer LSB), overflow bits and sigma-delta purposes. The total achievable resolution is 18-bits for frequencies close to the carrier frequency. It is noted that the use of 4×/1× devices is for illustration purposes only as Nx devices may be used, where N is 2, 4, 8, etc. In the case of N=8, for example, seven integer LSB and overflow devices would be used rather than three as in the example shown. The principles of the predistortion mechanism, however, can be applied regardless of the value of N.

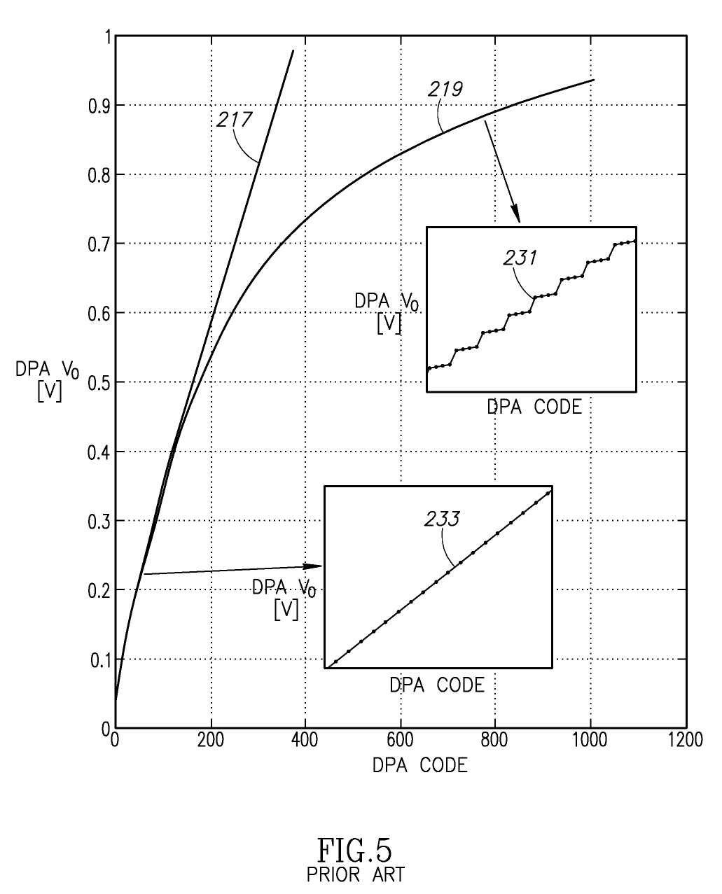

Ideally, the 1× sized transistors should be exactly one fourth the size of the 4× sized transistors. This means that the current contribution of the 1× transistors is exactly one fourth that of the 4× sized transistors. In reality, however, mismatches exist between the 1× and 4× sized transistors. The effects of this mismatch were shown and described in connection with FIGS. 5 and 6.

To compensate for the MSB/LSB device mismatch, the present invention provides a device mismatch predistortion mechanism. A block diagram illustrating a portion of a polar transmitter signal path incorporating the device mismatch predistortion mechanism of the present invention is shown in FIG. 11. The circuit, generally referenced 220, comprises a cordic and polar signal processing block 222 and device mismatch predistortion block 224. The cordic and polar signal processing block is operative to generate the ACW_IN signal 226 and the FCW signal 228, which is sent to the DFC. The ACW_IN signal is input to the device mismatch predistortion block 224 which functions to generate the ACW_OUT signal 229 then sent to the DRAC. A detailed description of the operation of the predistortion block 224 is provided infra.

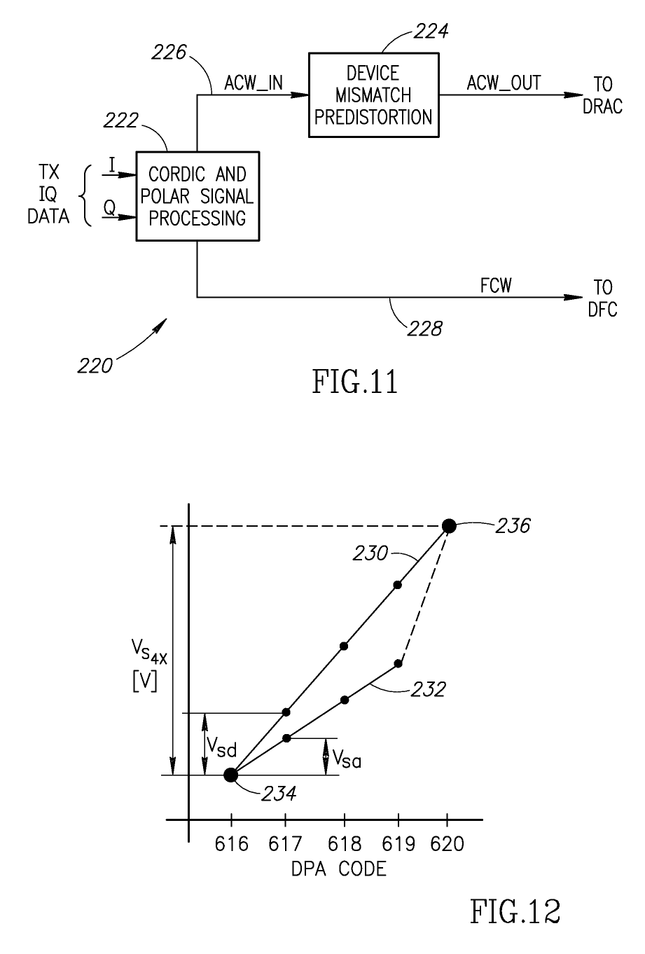

A graph illustrating a zoomed in version of the MSB/LSB device mismatch at high DPA input codes is shown in FIG. 12. The graph better illustrates the instantaneous effects of the MSB/LSB segmentation ratio mismatch resulting in code-to-voltage slope variation. The 4× step size is Vs_{4×} and the desired 1× step size V_{sd} is exactly ¼th of Vs_{4×}. The heavy dots 234 and 236 represent two 4× devices in sequence, corresponding to DPA input codes 616 and 620, respectively. The actual physical 1× step size, on the other hand, is Vₛₐ (which is smaller than V_{sd} as shown in the example figure, but may be larger in some cases). If the number of 1× steps is increased monotonically, it will result in a straight line 232 that has a different slope and tends to diverge from the desired DPA slope 230. Note that the common starting point of the two lines is the DPA output voltage for the 154^{th} MSB device (or code 616).

Let us assume that the value of the four unit-weighted (i.e. 1×) LSB bits at a certain instant of time is N. Then, if we connect the bits to the DPA 1× transistors directly, the equivalent voltage output will be N×Vₛₐ. But if we scale N by the ratio V_{sd}/Vₛₐ with fractional precision using sigma-delta dithering before it is passed to the DPA, then the DPA output voltage will be N×V_{sd}/Vₛₐ×Vₛₐ=N×V_{sd}, which is the desired linear output voltage. Therefore, once the MSB/LSB ratio mismatch is known precisely, the amplitude modulation input digital code to the DPA is predistorted to compensate for this artifact. Due to compression and the presence of the device level random variations in the MSB/LSB transistors, however, this MSB/LSB ratio mismatch cannot be characterized reliably in a straightforward manner. It has been determined, however, that such an estimate can be predicted accurately using power spectral density (PSD) of the differential DPA steps.

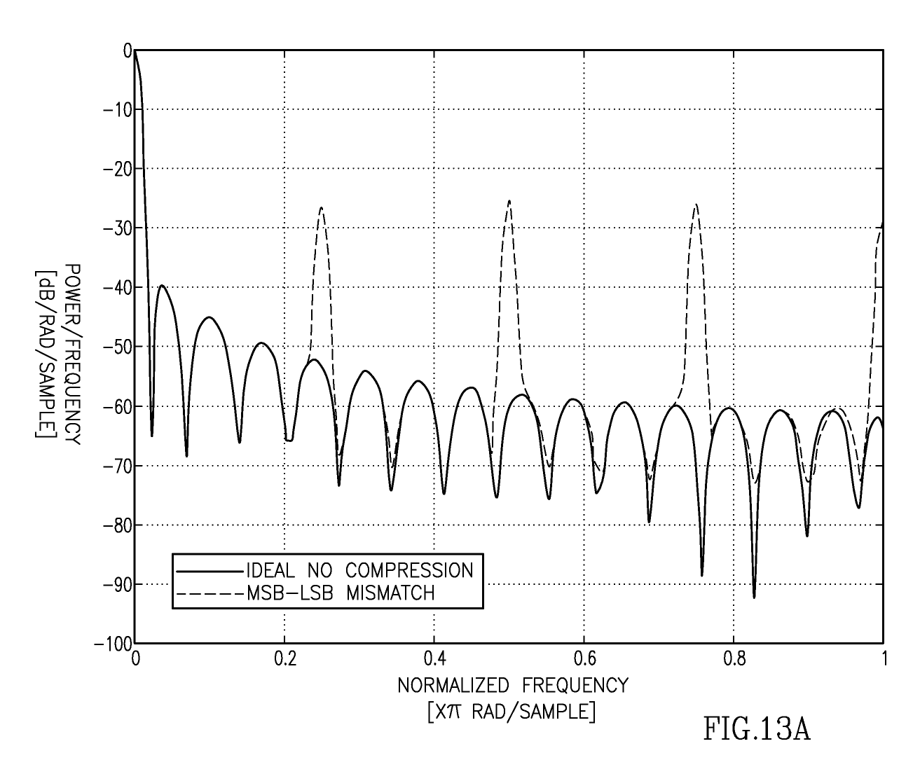

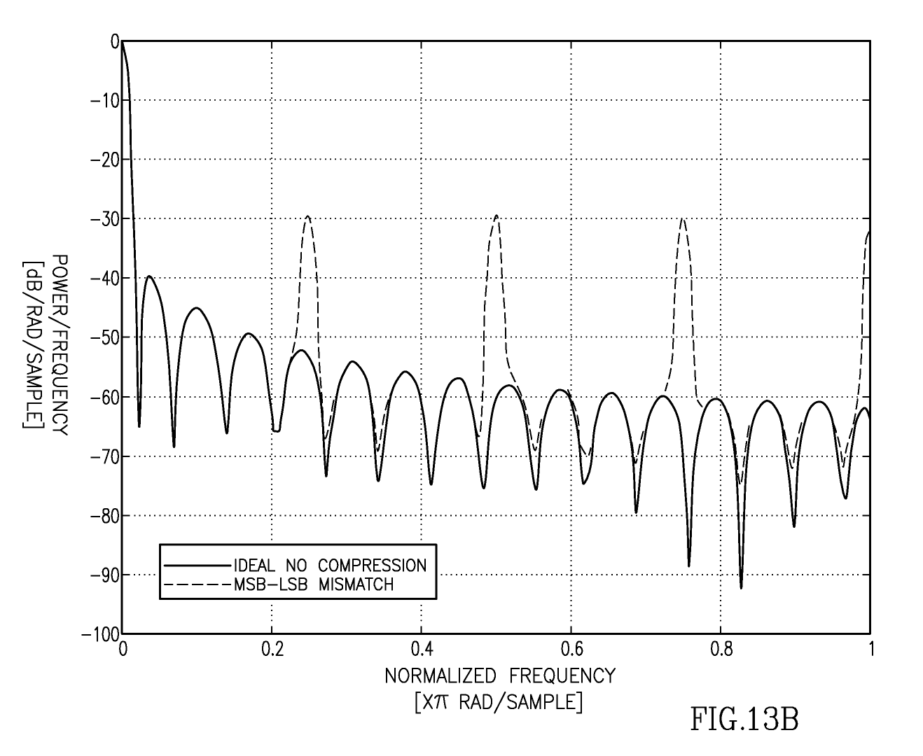

Graphs illustrating the normalized power spectral density (PSD) of the DPA differential step size in the presence of MSB/LSB ratio mismatch and device variability for two different ratios are shown in FIG. 13A (MSB step size 30% larger than corresponding LSB step size) and 13B (MSB step size 20% larger than corresponding LSB step size). Assuming DPA codes are swept at the normalized frequency of fₛ, then the LSB to MSB transitions will be hit fₛ/N times. This fact manifests itself in the shown single sided spectrum as N/2 spectral peaks, N being the number of LSB transistors that ideally equal an MSB transistor. The single sided spectrum has been plotted as 10×log(ΔVₒ^{DPA}). Further, the ratio mismatch, r_{ML}, between MSB/LSB transistors can be estimated by the relative level of the DNL spectral peaks caused by the ratio mismatch, i.e.,

r_{ML}=N·10^{(P}^{₁}^{-3)/20} (9)

where P₁ is the level of the first harmonic peak due to the presence of the device ratio mismatch. 3 dB is subtracted due to the use of a single sided spectrum. Equation 9 provides the correct ratio estimate but it cannot discriminate whether the MSB step is more or less than the N×LSB steps. This can be estimated using the following relation:

sign(10×log(max(ΔVₒ^{DPA})·min(ΔVₒ^{DPA})/mean²(ΔVₒ^{DPA}))) (10)

Once the ratio (also referred to as correction value) is correctly estimated, the ratio can be used to digitally predistort the DPA digital input codes. This improves the close-in spectral mask of the EDGE-class TX, which may otherwise fail the stringent spurious limits imposed by the wireless standard as well as coexistence requirements with other radios.

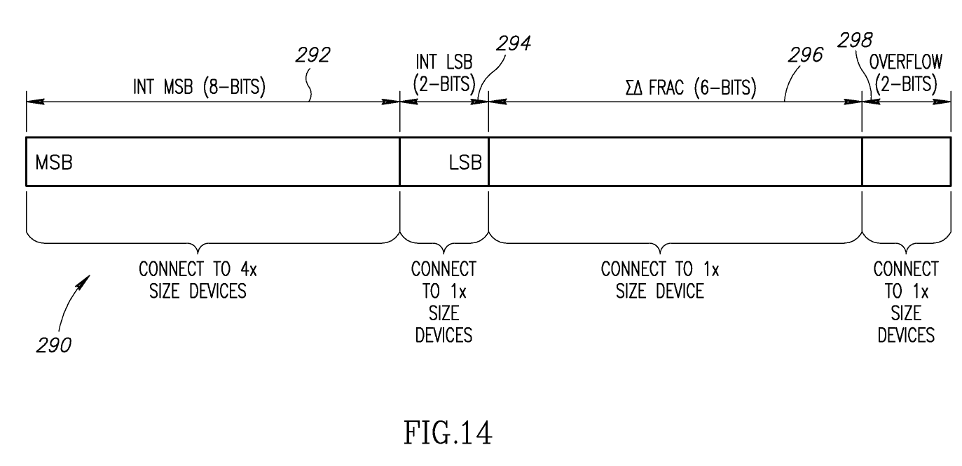

A diagram illustrating the amplitude control word (ACW) bits connected to different size devices is shown in FIG. 14. The ACW_OUT bit output of the predistortion block 224 (FIG. 11), generally referenced 290, comprises an 8-bit integer MSB portion 292 connected to 4× size devices, a 2-bit integer LSB portion 294 connected to 1× size devices, a 6-bit sigma-delta fractional portion 296 connected to a 1× size device (after passing through a sigma-delta modulator circuit whose output is a 1-bit signal), and a 2-bit overflow portion 298 connected to 1× size devices.

Note that the overflow bits are needed in the event V_{sd} is greater than Vₛₐ. In this case, the ratio V_{sd}/Vₛₐ will be greater than one and the redundant coding is thus used. Thus, in some instances, the predistortion correction results in an overflow which makes the value N×V_{sd}/Vₛₐ greater than 8-bits. In order to accommodate any possible overflow, three extra ‘auxiliary’ 1× sized devices 214 (FIG. 10) are provided to carry the overflow bits when they occur.

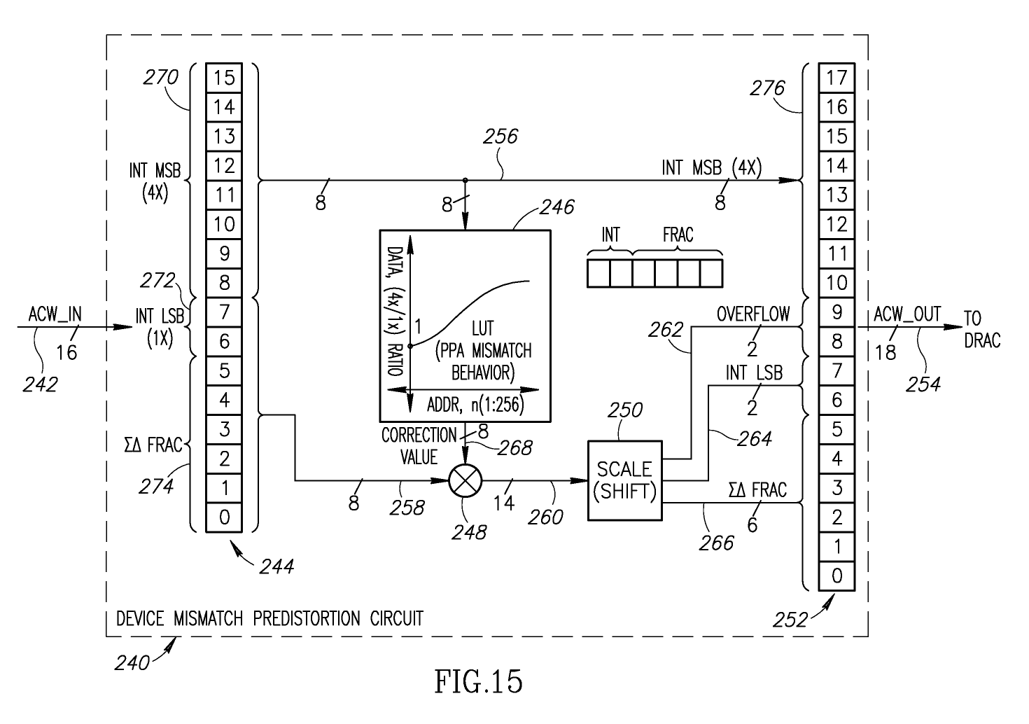

The operation of the predistortion circuit will now be described in more detail. A block diagram illustrating an example device mismatch predistortion circuit of the present invention is shown in FIG. 15. The device mismatch predistortion circuit, generally referenced 240, comprises a 16-bit input register 244, predistortion look up table (LUT) 246, fixed bit multiplier 248, scale (shifter) circuit 250 and 18-bit output register 252.

In operation, the 16-bit ACW_IN word 242 in clocked into the input register 244. The ACW_IN word comprises eight integer MSB binary-coded bits [15:8] 270, two integer LSB binary-coded bits [7:6] 272 and six sigma-delta fractional binary-coded bits [5:0] 274. The eight integer MSB bits pass through to bits [17:10] in the output register 252 and are also connected to the address input of the predistortion LUT 246. The six bit correction values 268 output of the LUT are multiplied by eight bits 258 comprising the integer LSBs and sigma-delta fractional bits. The scale block 250 functions to scale the 14-bit result 260 to generate as output two overflow binary-coded bits [9:8] 262, two integer LSB binary-coded bits [7:6] 264 and six sigma-delta fractional binary-coded bits [5:0] 266. The 18-bit output ACW_OUT word 254 is passed to the DRAC for further processing. Note that the six sigma-delta fractional bits are input to a first-order sigma-delta modulator, the one bit output of which is applied to the single 1× transistor 218 (FIG. 10).

The contents of the predistortion table are typically generated a priori based on measured data and/or calculations as described supra. In accordance with the example embodiment presented herein, the table comprises 256 correction value entries. As described supra, a single correction value for all input codes is not sufficient to compensate for device mismatches in the DPA. This is because the mismatch ratio is not constant through the range of DPA digital input codes. Thus, one correction value per M input codes is required, where M can be 2, 3, 4 or 5, etc. In this example case, M is four. The codes generated are stored in the table for use during operation of the DPA.

Each entry in the table is 6-bits and may comprise a 2-bit integer field [5:4] and 4-bit fractional field [3:0] to be able to handle correction ratios larger or smaller than one. With 256 entries, the correction multiplier value changes every four input codes. Thus, the eight MSB bits are used to address the table. The correction values read out of the table are multiplied, however, by the eight LSB bits.

Note that if the correction value is less than one, then the multiplication product is always less than the input and will not generate an overflow. For correction factors greater than one, however, the multiplication product is always greater than the input and thus the overflow bits are needed in order to avoid a loss in resolution.

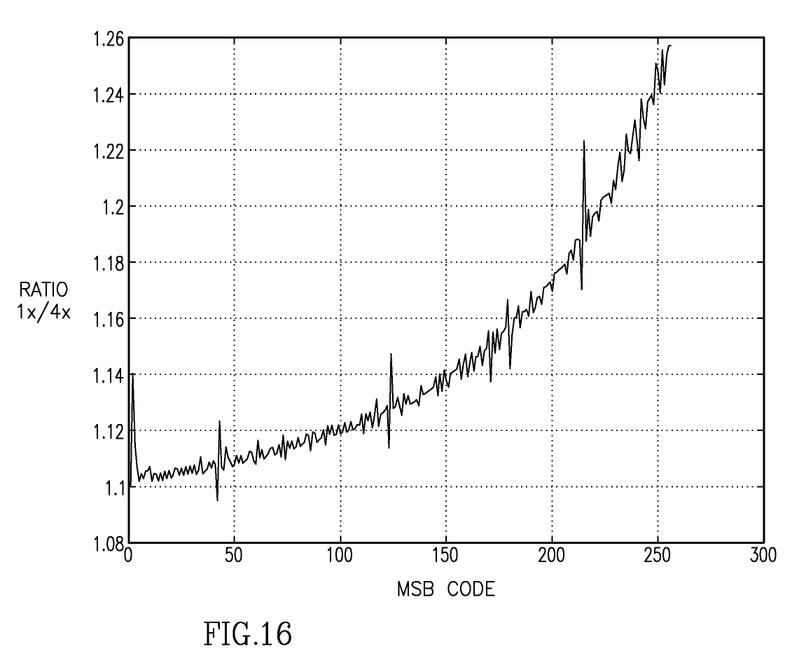

A graph illustrating an example ratio curve stored in the LUT for correcting device mismatch is shown in FIG. 16. The correction values used to generate this graph represent the exact correction values (i.e. no rounding off, truncating, etc.). Note that the shape of the ratio (or correction) curve is substantially inverse to that of the mismatch curve of FIG. 5.

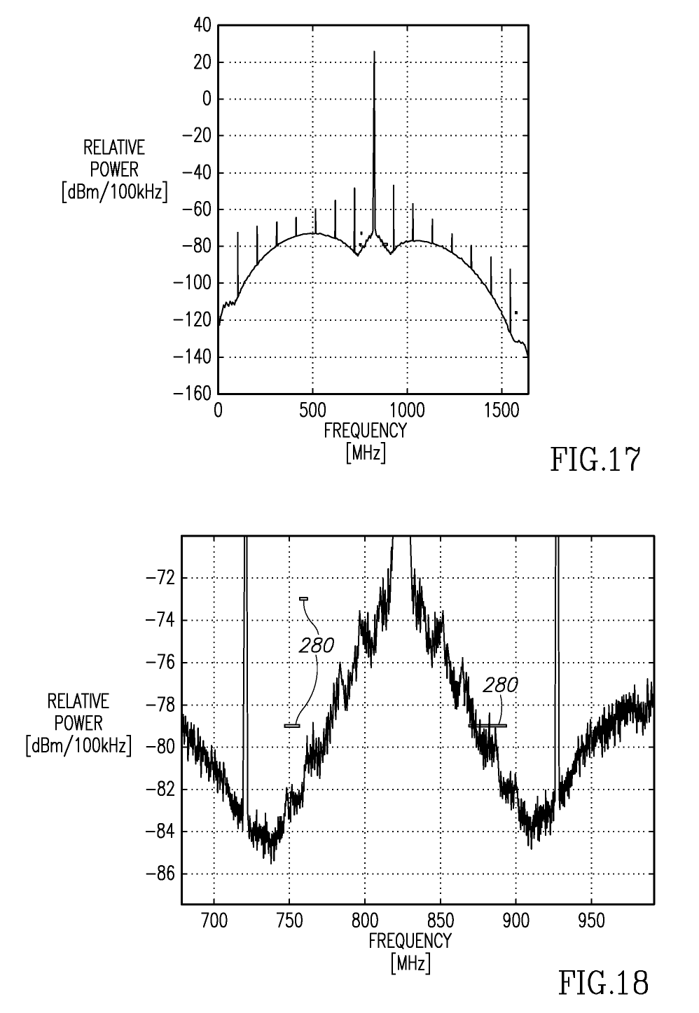

A graph illustrating the frequency spectrum output without device mismatch predistortion is shown in FIG. 17. A zoomed in portion of the graph of FIG. 17 showing a spectral mask violation is shown in FIG. 18. The flat indicators 280 represent spectral mask requirements for the GSM wireless standard. Thus, without the benefit of the device mismatch predistortion mechanism of the present invention, a violation of the transmitter output occurs at approximately 875 MHz.

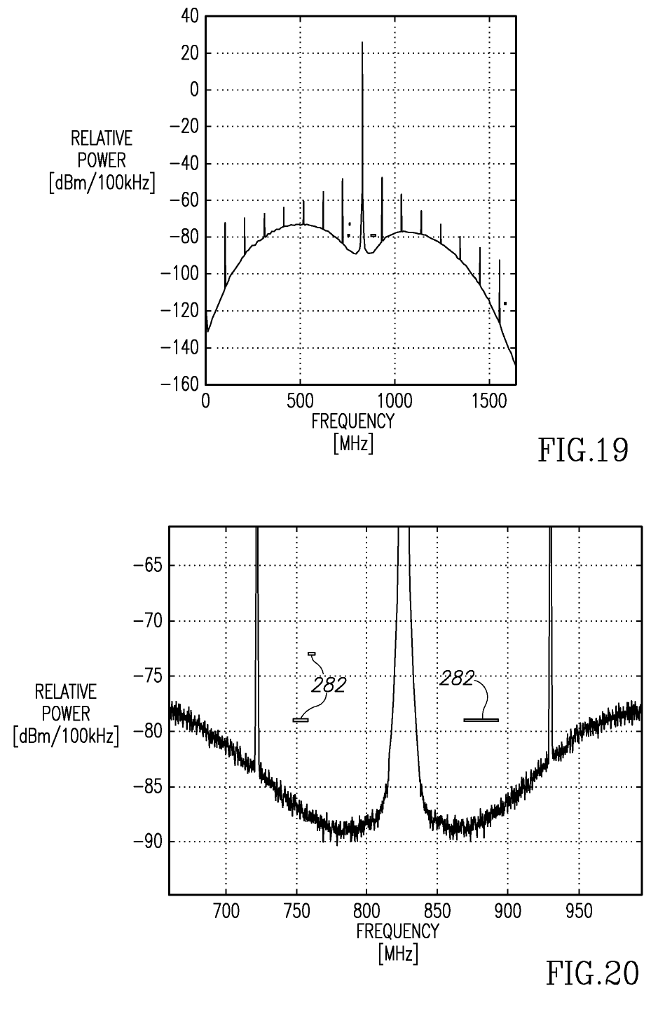

A graph illustrating the frequency spectrum output with device mismatch predistortion is shown in FIG. 19. A zoomed in portion of the graph of FIG. 19 showing no spectral mask violation is shown in FIG. 20. The flat indicators 282 represent spectral mask requirements for the GSM wireless standard. Thus, the use of the device mismatch predistortion mechanism of the present invention avoids any spectral mask violations in the transmitter output. In addition to the smoother response, the output attenuation at around the main frequency spike exhibits steeper roll-off and increased attenuation of approximately 5 dB.

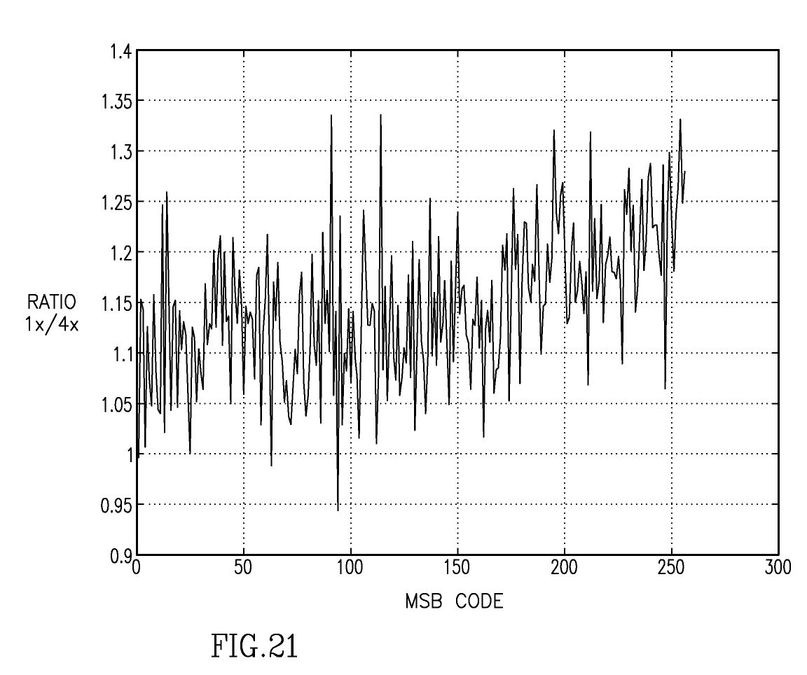

A graph illustrating an example ratio curve stored in the LUT for correcting device mismatch whose entries are less accurate than those of FIG. 16 is shown in FIG. 21. Note that use of less accurate estimates of the ratio curve results in a much less smooth ratio curve.

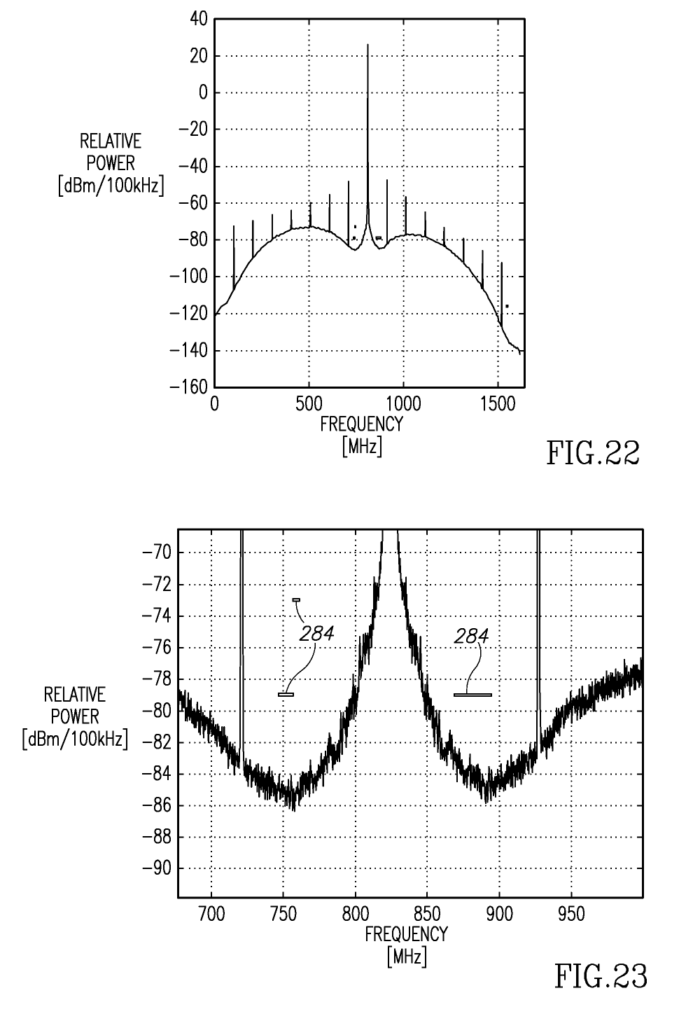

A graph illustrating the frequency spectrum output with device mismatch predistortion using the curve of FIG. 21 is shown in FIG. 22. A zoomed in portion of the graph of FIG. 22 showing no spectral mask violations is shown in FIG. 23. The flat indicators 284 represent spectral mask requirements for the GSM wireless standard. Even with the use of less accurate estimates for the ratio, the use of the device mismatch predistortion mechanism of the present invention still avoids any spectral mask violations in the transmitter output. The response here is not as good as in FIGS. 19 and 20 but more than meets the spectral mask requirements.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. As numerous modifications and changes will readily occur to those skilled in the art, it is intended that the invention not be limited to the limited number of embodiments described herein. Accordingly, it will be appreciated that all suitable variations, modifications and equivalents may be resorted to, falling within the spirit and scope of the present invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A method of transistor mismatch compensation for use in digital power amplifier, said method comprising the steps of:
receiving a digital amplitude code representing a desired amplifier output power level;
determining a predistortion correction value based on said digital amplitude code; and
applying said predistortion correction value to said digital amplitude code thereby compensating the output of said amplifier for transistor mismatch effects therein.

2. The method according to claim 1, wherein said predistortion correction value is obtained from a look up table (LUT) adapted to store a plurality of predistortion correction values.

3. The method according to claim 2, wherein said LUT is populated with correction values calculated based on the ratio of desired amplifier output voltage to measured amplifier output voltage.

4. The method according to claim 2, wherein said LUT is addressed by a plurality of most significant bits (MSBs) of said digital amplitude code.

5. The method according to claim 1, wherein said predistortion correction value is determined based a plurality of most significant bits (MSBs) of said digital amplitude code.

6. The method according to claim 1, wherein said predistortion correction value is applied to a plurality of least significant bits (LSBs) of said digital amplitude code.

7. The method according to claim 1, wherein said transistor mismatch comprises the mismatch between LSB first size amplifier transistors and MSB second size amplifier transistors.

8. The method according to claim 1, wherein said step of applying said predistortion correction value is performed only on LSB first size weighted amplifier transistors.

9. The method according to claim 1, wherein said step of applying said predistortion correction value is performed only on fractional bits of said digital amplitude code.

10. The method according to claim 1, wherein said step of applying said predistortion correction value is performed only on integer and fractional bits of said digital amplitude code.

11. A method of pre-distortion for transistor mismatch compensation in a digital power amplifier, said method comprising the steps of:
receiving a digital amplitude code representing a desired amplifier output power level; and
applying a predistortion correction value determined in accordance with said digital amplitude code to a portion of said digital amplitude code corresponding to one or more amplifier transistors to be compensated for mismatch effects.

12. The method according to claim 11, wherein said predistortion correction value is calculated based on the ratio of desired amplifier output voltage to measured amplifier output voltage.

13. The method according to claim 11, wherein said transistor mismatch comprises the mismatch between LSB first size amplifier transistors and MSB second size amplifier transistors.

14. The method according to claim 13, wherein said portion of said digital amplitude code corresponds to LSB first size weighted amplifier transistors.

15. The method according to claim 11, wherein said portion of said digital amplitude code corresponds only to fractional bits of said digital amplitude code.

16. The method according to claim 11, wherein said step of applying a predistortion correction value is applied to integer and fractional bits of said digital amplitude code.

17. The method according to claim 11, wherein predistortion correction values are stored in a look up table (LUT) addressed by a plurality of integer most significant bits (MSBs) of said digital amplitude code.

18. An apparatus for transistor mismatch compensation in a digital power amplifier, comprising:
an input for receiving a digital amplitude code represented a desired amplifier output power level;
a table coupled to said input for storing a plurality of correction values; and
a correction circuit operative to apply correction values output of said table to said digital amplifier code thereby compensating the output of said amplifier for transistor mismatch effects.

19. The apparatus according to claim 18, wherein said transistor mismatch comprises the mismatch between LSB first size amplifier transistors and MSB second size amplifier transistors.

20. The apparatus according to claim 19, wherein said table stores LSB first size weighted transistor correction values addressed on an MSB second size weighted size transistor basis.

21. The apparatus according to claim 18, wherein said correction circuit is operative to apply said correction values to a fractional portion of said digital amplitude code.

22. The method according to claim 18, wherein said table is addressed by a plurality of most significant bits (MSBs) of said digital amplitude code.

23. The apparatus according to claim 18, wherein said table is addressed by an integer portion of said digital amplitude code.

24. The apparatus according to claim 18, wherein said correction circuit comprises a multiplier operative to multiply least significant bit (LSB) digital amplifier code bits with a corresponding correction value generated by said table in accordance with a most significant bit (MSB) portion of said digital amplitude code.

25. The apparatus according to claim 18, further comprising one or more overflow bits generated for correction values greater than one.

26. An apparatus for compensating an amplifier for transistor mismatch effects, comprising:
an input signal for receiving a digital amplitude code represented a desired amplifier output power level;
a lookup table (LUT) coupled to said input signal for storing a plurality of correction values;
a correction circuit operative to apply correction values output of said table to an integer least significant bit (LSB) portion of said digital amplifier code thereby compensating the output of said amplifier for transistor mismatch effects; and
an output register for storing a non-compensated integer most significant bit (MSB) portion and a compensated LSB portion of said amplitude code.

27. The apparatus according to claim 26, wherein said output register comprises one or more overflow bits generated for correction values greater than one.

28. The apparatus according to claim 26, wherein said lookup table is addressed by an integer MSB portion of said digital amplitude code.

29. The apparatus according to claim 26, wherein said correction circuit comprises a multiplier operative to multiply LSB digital amplifier code bits with a corresponding correction value generated by said table in accordance with an integer MSB portion of said digital amplitude code.

30. An apparatus for compensating for device mismatch effects in a digital power amplifier (DPA), comprising:
a single segmented bank of amplifier transistors, comprising:
a most significant bit (MSB) bank comprising a first plurality of devices having a first size;
a least significant bit (LSB) bank comprising a second plurality of devices having a second size;
a predistortion circuit operative to compensate a DPA input signal for mismatches between said MSB bank devices and said LSB bank devices to yield a compensated DPA input signal thereby, said DPA input signal comprising an LSB portion and an MSB portion; and
wherein compensation of said DPA input signal by said predistortion circuit is dependent on said MSB portion of said DPA input signal.

31. A method of generating a plurality of correction values for use in an amplifier transistor mismatch pre-distortion circuit, said amplifier having a segmented bank of transistors incorporating first transistors of a first size and second transistors of a second size, said method comprising the steps of:
determining desired first voltage steps for each of said first transistors;
determining desired second voltage steps for each of said second transistors in accordance with said desired first voltage steps;
measuring actual third voltage steps for said second transistors; and
calculating said correction values as a function of the ratio of said second voltage steps to said third voltage steps.

32. A polar radio frequency (RF) transmitter, comprising:
means for generating a frequency command and an amplitude command in accordance with said modified TX IQ data samples;
a pre-distortion circuit for compensating a digital power amplifier (DPA) for transistor mismatch effects, said pre-distortion circuit operative to:
receive said digital amplitude command representing a desired amplifier output power level;
determine a predistortion correction value based on said digital amplitude command;
apply said predistortion correction value to said digital amplitude command to generate a compensated digital amplitude command which effectively compensates the output of said DPA for transistor mismatch effects therein;
a frequency synthesizer operative to generate an RF signal having a frequency in accordance with a frequency reference input and said frequency command; and
said digital power amplifier (DPA) operative to receive said RF signal and to generate a modulated RF output signal in proportion to said compensated amplitude command.

33. A method of device mismatch compensation for use in a radio frequency digital to analog converter (RF DAC), said method comprising the steps of:
receiving an input code representing a desired RF DAC output;
determining a predistortion correction value based on said input code; and
applying said predistortion correction value to said input code thereby compensating the output of said RF DAC for device mismatch effects therein.
